(19) United States
(12) Patent Application Publication
(10) Pub. No.: US 2026/0343913 A1
(43) Pub. Date: Oct. 29, 2026

(54) DIAMOND SEMICONDUCTOR DEVICE

(71) Applicants: Advanced Diamond Holdings, LLC, Beltsville, MD (US); SRI International, Menlo Park, CA (US)

(72) Inventors: John P. Ciraldo, Clarksburg, MD (US); Christopher Chua, San Jose, CA (US); Thomas Wunderer, Santa Cruz, CA (US)

(21) Appl. No.: 19/662,799

(22) Filed: Apr. 29, 2026

Related U.S. Application Data
(60) Provisional application No. 63/796,901, filed on Apr. 29, 2025.

(51) Int. Cl. H10D 8/00; H10D 62/82; H10P 10/00; H10P 95/90

(52) U.S. Cl. CPC H10D 8/411; H10D 62/82; H10P 10/128; H10P 95/90

(57) ABSTRACT

A method forms a hybrid semiconductor switch. The method polishes the surface of a synthetic diamond substrate and wafer bonds the diamond substrate with InAlGaN heterostructure. A surface of the heterostructure is positioned against the polished surface of the diamond substrate. Pressure is applied to enhance contact between the surfaces, and temperature is applied to induce interaction of surface atoms. The bonded structure includes a p-n or p-i-n junction. The p-n or p-i-n junction allows electrical current flow if forward biased and blocking electrical current flow if reverse biased

### PRIORITY

This patent application claims priority from provisional U.S. patent application No. 63/796,901, filed Apr. 29, 2025, entitled, “DIAMOND SEMICONDUCTOR DEVICE,” and naming John Ciraldo, Christopher Chua, and Thomas Wunderer as inventors, the disclosure of which is incorporated herein, in its entirety, by reference.

### FIELD

Illustrative embodiments generally relate to diamond-based semiconductor devices, and more particularly, to ultra-wide bandgap power switches formed by heterogeneous integration of p-type diamond substrates with III-Nitride heterostructures for high-voltage, high-power electronic applications.

### BACKGROUND

A typical problem with switches for high-power applications is heat generation and thermal management, arising from energy losses during the “on” state and switching losses during transitions between “on” and “off.” These losses can lead to significant heat buildup, causing overheating, reduced efficiency, and eventual device failure if not properly managed. The high thermal stress can degrade materials, accelerate aging, and result in reliability issues.

### SUMMARY OF VARIOUS EMBODIMENTS

In accordance with one embodiment, a semiconductor switch includes a synthetic diamond substrate, an In(x)Al(y)Ga(1-x-y)N layer disposed on a surface of the diamond substrate, and a p-n junction configured such that current flows along a direction perpendicular to the surface of the diamond substrate. T the diamond, the In(x)Al(y)Ga(1-x-y)N layer, and the p-n junction together form a switch. The switch further includes metal contacts in electrical contact with the diamond substrate and with the In(x)Al(y)Ga(1-x-y)N layer. The switch is configured to turn on when a voltage bias is applied across the p-n junction.

In various embodiments, the p-n junction is disposed at an interface between the diamond and the InAlGaN, and the diamond may be p-type doped while the InAlGaN is n-type doped, for example with boron as a p-type dopant and one or more of silicon, germanium, or oxygen as an n-type dopant, or alternatively with n-type behavior induced by grading an aluminum composition from low to high in a growth direction of an Al- or Ga-polar substrate or template. In other embodiments, the diamond is n-type doped and the InAlGaN is p-type doped, for example with n-type dopants including phosphorous or nitrogen and p-type dopants including magnesium, zinc, or beryllium.

In some embodiments, the InAlGaN includes a heterostructure comprising multiple alloy compositions of indium, aluminum, gallium, and nitrogen, including embodiments in which the composition is gradually varied to induce n-type or p-type conductivity through polarization doping. In certain embodiments, the p-n junction is formed within the heterostructure, and the heterostructure may include epitaxial layers having bandgaps between about 4 eV and about 6.2 eV, and may further include superlattices, short-period superlattices, or graded alloy compositions, optionally including polarization-doping structures that enhance free carrier generation.

In some embodiments, the applied voltage exceeds about 5 kV without electrical breakdown. The InAlGaN may be bonded to the diamond substrate, may be provided as an epitaxial layer, or may be epitaxially deposited on the diamond substrate. In some embodiments, the In(x)Al(y)Ga(1-x-y)N layer disposed on the diamond substrate has a thickness between about 50 microns and about 650 microns. In other embodiments, the In(x)Al(y)Ga(1-x-y)N includes a graded AlGaN layer having a thickness between about 100 nm and about 500 nm and transitioning in composition from about 70% aluminum/30% gallium to about 100% aluminum.

In accordance with another embodiment, a hybrid semiconductor switch includes a synthetic diamond substrate, and an epitaxial InAlGaN thin film disposed on the diamond substrate. A p-n junction is configured such that current flows along a direction perpendicular to the diamond substrate. An intrinsic, undoped film may be disposed between regions of the p-n junction to form a p-i-n structure. The diamond, the InAlGaN, and the p-i-n junction together form a switch. The switch includes metal contacts in electrical contact with the diamond substrate and with the InAlGaN thin film. Applying a voltage bias across the p-n junction turns the switch on or off.

In various embodiments, the intrinsic material includes one or more of SiO2, Al2O3, AlN, AlGaN, SiN, or HfO2.

Throughout this description, many examples and figures refer to n-type AlGaN as the III-N material for purposes of illustration. It should be understood that these examples are not limited to n-type AlGaN and are intended to encompass p-type AlGaN, as well as any composition of In(x)Al(y)Ga(1-x-y)N, including ternary alloys (e.g., AlGaN, InAlN, InGaN), quaternary alloys (e.g., InAlGaN), and graded or layered combinations thereof. Similarly, references to specific doping types (e.g., n-type or p-type) in the context of the III-N material are illustrative; various embodiments may reverse the doping polarities or employ intrinsic, undoped, or polarization-doped regions as described herein. Accordingly, the use of n-type AlGaN in the examples should be understood as representative of the broader class of In(x)Al(y)Ga(1-x-y)N materials unless the context clearly indicates otherwise.

In accordance with yet another embodiment, a method for forming a hybrid semiconductor switch includes polishing a surface of a synthetic diamond substrate. An InAlGaN heterostructure is wafer bonded on the diamond substrate by disposing a surface of the heterostructure against the polished surface of the diamond substrate, applying pressure to enhance contact between the surfaces, and applying temperature to induce interaction of surface atoms. The bonded structure includes a p-n or p-i-n junction extending along a direction perpendicular to the diamond substrate. The p-n or p-i-n junction allows electrical current flow when forward biased and blocks electrical current flow when reverse biased.

In various embodiments, the method further includes performing one or more thermal anneals after wafer bonding to induce atomic diffusion at the interface, activating one or both surfaces with plasma treatment prior to bonding, and thinning one or both substrates using mechanical polishing, wet chemical etching, or a combination thereof, including thinning to a thickness between about 50 microns and about 1 mm. The method may further include removing the InAlGaN heterostructure from a growth substrate using one or more of laser lift-off, selective wet chemical etching, ion-implant smart cut peeling, or spalling, removing the growth substrate, and optionally performing a flip-chip process.

In accordance with an embodiment, a semiconductor device includes a diamond body having a first conductivity type region and a III-nitride semiconductor body having a second conductivity type region opposite the first conductivity type. The III-nitride semiconductor body is directly bonded to the diamond body at an interface. The device includes a junction disposed in a current path extending in a direction generally perpendicular to a major surface of the diamond body.

In various embodiments, the junction is formed at the interface between the diamond body and the III-nitride semiconductor body, and the device is configured to operate as a semiconductor switch that selectively permits and blocks current flow in response to an applied voltage. The III-nitride semiconductor body may include In(x)Al(y)Ga(1-x-y)N, where x and y are between 0 and 1. The direct bond may be formed without an intervening adhesive or filler layer, and may include bonds formed by contacting surfaces having exposed dangling bonds, such as where surface termination species have been removed prior to bonding and the bonding is performed under reduced pressure or vacuum. At least one bonded surface may have a surface roughness of less than about 3 angstroms Ra, and the diamond body and the III-nitride semiconductor body may be bonded over substantially corresponding wafer-scale surfaces.

In some embodiments, the diamond body has a thickness of at least about 5 microns and is configured to conduct heat from the junction toward a thermal extraction structure. At least a portion of the diamond body may include homoepitaxially grown diamond. The diamond body may further include isotopically engineered diamond, such as diamond enriched in carbon-12, including embodiments in which a region of the diamond body adjacent the interface is enriched in carbon-12 and extends at least about 5 microns from the interface, while a region of the diamond body distal from the interface has a different isotopic composition.

In various embodiments, the III-nitride semiconductor body includes a compositionally graded region, wherein a first portion of the graded region is selected based on compatibility with a growth substrate and a second portion adjacent the interface is selected to provide a desired bandgap and/or band alignment relative to the diamond body, the composition optionally varying continuously through the graded region. The device may further include an intrinsic layer disposed between the first and second conductivity type regions to form a p-i-n structure, or the junction may instead be formed within the III-nitride semiconductor body. In some embodiments, a p-type III-nitride layer is disposed between the diamond body and an n-type III-nitride region.

In some embodiments, the device includes electrical contacts in communication with the diamond body and the III-nitride semiconductor body, such as metal contacts. Alternatively or additionally, a backside region of the diamond body may include a highly doped diamond contact region configured to provide metal-like conductivity, optionally with a metal layer disposed on the highly doped diamond contact region.

In accordance with another embodiment, a method forms a semiconductor device by providing a diamond body and a III-nitride semiconductor body. The method prepares a surface of the diamond body and a surface of the III-nitride semiconductor body. The surfaces are directly bonded to form an interface. A junction is formed in a current path extending generally perpendicular to the interface.

In various embodiments, preparing the surfaces includes removing surface termination species to expose dangling bonds, and the direct bonding may be performed under reduced pressure or vacuum. The method may further include thinning or removing a growth substrate of the III-nitride semiconductor body after bonding.

In accordance with yet another embodiment, a semiconductor structure includes a diamond layer and a III-nitride layer directly bonded to the diamond layer, wherein the structure includes a junction disposed in a vertical current path and the diamond layer is positioned to thermally conduct heat from the junction.

Illustrative embodiments are implemented as a computer program product having a computer usable medium with computer readable program code thereon. The computer readable code may be read and utilized by a computer system in accordance with conventional processes.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Those skilled in the art should more fully appreciate advantages of various embodiments of the invention from the following “Description of Illustrative Embodiments,” discussed with reference to the drawings summarized immediately below.

FIG. 1A shows an AFM image of homoepitaxial AlN on bulk AlN in accordance with illustrative embodiments.

FIG. 1B graphically shows a low-temperature photoluminescence spectrum of AlN in accordance with illustrative embodiments.

FIG. 1C graphically shows an XRD reciprocal space map of a pseudomorphic AlGaN film on bulk AlN in accordance with illustrative embodiments.

FIGS. 2A-2D show processes of producing a semiconductor device in accordance with illustrative embodiments.

FIG. 3 schematically shows a p-type diamond wafer and an AlN wafer on a growth substrate in accordance with illustrative embodiments.

FIG. 4 schematically shows an n-AlGaN film epitaxially grown on an AlN wafer in accordance with illustrative embodiments.

FIG. 5 schematically shows a p-type diamond wafer directly bonded to an n-AlGaN film on an AlN wafer and growth substrate in accordance with illustrative embodiments.

FIG. 6 schematically shows the structure of FIG. 5 with the growth substrate and AlN film removed in accordance with illustrative embodiments.

FIG. 7 schematically shows a p-n junction with metal contacts deposited on the p-type diamond and n-AlGaN in accordance with illustrative embodiments.

FIG. 8 schematically shows n-AlGaN and p-AlGaN films epitaxially grown on an AlN template and growth substrate in accordance with illustrative embodiments.

FIG. 9 schematically shows p-type diamond bonded to a p-AlGaN/n-AlGaN structure on an AlN template and growth substrate in accordance with illustrative embodiments.

FIG. 10 schematically shows the structure of FIG. 9 with metal contacts deposited on the p-type diamond and n-AlGaN in accordance with illustrative embodiments.

FIG. 11 schematically shows a p-type diamond directly bonded to an n-AlGaN film on an AlN template and growth substrate in accordance with illustrative embodiments.

FIG. 12 schematically shows the structure of FIG. 11 with metal contacts deposited in accordance with illustrative embodiments.

FIG. 13 schematically shows a p-type diamond bonded to a p-AlGaN/n-AlGaN structure on an AlN template and growth substrate in accordance with illustrative embodiments.

FIG. 14 schematically shows the structure of FIG. 13 with the p-AlGaN locally etched in accordance with illustrative embodiments.

FIG. 15 schematically shows the structure of FIG. 14 with metal contacts deposited on the p-type diamond and n-AlGaN in accordance with illustrative embodiments.

FIG. 16 schematically shows a p-i-n junction having an undoped material between a p-type diamond and n-AlGaN in accordance with illustrative embodiments.

FIG. 17 graphically shows a compositional grading profile of an AlGaN layer, illustrating the transition from a lattice-matching region near the growth substrate to a bandgap-matching region near the diamond bonding interface, in accordance with illustrative embodiments.

FIG. 18 schematically shows a cross-section of a semiconductor device having an isotopically enriched Carbon-12 diamond region adjacent to the direct bond interface and a mixed-isotope diamond region distal from the interface, in accordance with illustrative embodiments.

FIG. 19 schematically shows a direct bonding process in four stages: (A) surface termination present on exposed surfaces, (B) ion cleaning in vacuum to remove surface termination, (C) dangling bonds exposed with unfilled electron orbitals, and (D) covalent bonds formed across the diamond/III-N interface, in accordance with illustrative embodiments.

FIG. 20A schematically shows a cross-section of the semiconductor device illustrating heat flow from the p-n junction through the diamond substrate to a cooling system in accordance with illustrative embodiments.

FIG. 20B schematically shows a qualitative temperature profile along the device stack of FIG. 20A, in accordance with illustrative embodiments.

FIGS. 21A-21B schematically show alternative backside contact configurations in accordance with illustrative embodiments.

FIGS. 22A-B schematically show the semiconductor device operating as a switch in a forward bias on-state and a reverse bias off-state, respectively, in accordance with illustrative embodiments.

FIG. 23 shows a ternary bandgap diagram for the In(x)Al(y)Ga(1-x-y)N material system, illustrating the relationship between elemental composition and bandgap energy, in accordance with illustrative embodiments.

### DESCRIPTION OF ILLUSTRATIVE EMBODIMENTS

Illustrative embodiments relate to heterogeneous diamond/III-nitride semiconductor devices that provide the thermal advantages of diamond together with the tunable electronic properties of III-nitride materials. Diamond is highly attractive for ultra-wide bandgap devices because of its large bandgap and exceptionally high thermal conductivity. However, in many practical implementations, it may be difficult to realize a fully diamond-based complementary junction device using diamond alone. Various embodiments therefore directly bond a diamond body, such as a p-type diamond body, to a III-nitride semiconductor body, including an n-type region, to form a vertical junction device that places highly thermally conductive diamond at or immediately adjacent the active junction region.

The III-nitride body may be compositionally engineered across its thickness. A first region nearer an original growth template may be selected with regard to epitaxial growth quality, crystalline quality, and compatibility with the growth template. A second region nearer the bonded diamond interface may be selected with regard to a desired bandgap, band alignment, barrier profile, carrier injection property, polarization effect, breakdown characteristic, or other electronic device property relative to the diamond. The compositional transition between these regions may be abrupt, graded, stepwise, or formed using a superlattice structure.

Preferably, various embodiments develop a substrate, semiconductor materials and fabrication processes for a vertical Ultra-Wide Band Gap (UWBG) power switch, capable of handling >5 kV, enabled through heterogeneous integration of highly thermally conductive p-type diamond substrates and n-type AlGaN heterostructures, operated in a vertical PN-diode array. Among other things, illustrative embodiments may be advantageous for applications in electric vehicles drivetrains, charge control, battery management, photovoltaic power converters, power supplies, RF and for numerous other commercial and military use cases in high-power electronics. Various advances are enabled by developing the concepts, semiconductor materials and fabrication methods, and delivering quantifiable prototype device metrics.

The type of UWBG device of various embodiments may solve three significant issues in today's state-of-the-art power electronics technology:
(1) Limitations in thermal management,
(2) Operation voltage, and
(3) Current handling capability.

Commercially available III-Nitride-based electronic devices typically are based on a lateral device architecture, i.e., realized as high electron mobility transistor (HEMT) using a polarization-induced, two-dimensional electron gas (2-DEG). Such transistors provide a high-frequency response and are already important for a multitude of civilian and military use cases, with moderate voltage (<650 V) requirements, including many relevant DoD applications in RF, RADAR, power electronics, and AC/DC and DC/DC power converters, etc. The desire to operate such WBG devices at higher power, however, is constrained by limitations in thermal conductivity, electrical breakdown field strength, and current handling capacity when using a lateral device architecture with a narrow 2-DEG channel of just a few nanometers.

In various embodiments, these limitations for operating such systems at higher power are overcome by implementing:
(1) diamond substrates, offering the highest thermal conductivity known material,
(2) reverting current flow in vertical direction via a vertical p-diamond/n-AlGaN device architecture with large current aperture, and
(3) enabling high voltage operation through implementing ultra-wide band gap semiconductor materials with high breakdown field strength (e.g., greater than 5 eV, for both diamond and AlGaN).

As an example, diamond substrates may be produced via a chemical vapor deposition (CVD) growth process and fabricated using a 2.45 GHz CVD processes. The wafer scale benefits from the scaling technology of various uses. To satisfy desirable electrical properties for device fabrication, some wafers, such as those used for device fabrication, may be grown in an environment enriched in boron to create boron-doped, p-type semiconductor grade material. For the development and demonstration of wafer finishing, the remaining wafers may be grown without the presence of boron and remain electrically insulating.

Initial diamond substrates may be 25 mm in diameter, with subsequent substrates provided up to 50 mm diameters. As such, illustrative embodiments may produce diamond substrates of between 25 mm and 50 mm. Of course, smaller diamond substrates may also be produced.

Insulating diamond substrates as described above may be used for developing and demonstrating an in-house polishing process using a 4-20 micron grit to mechanically smooth the substrate surface. A dry, plasma-based process maybe employed to both remove subsurface damage from the mechanical polish (typical depths of damage are approximately 3 microns), as well as to achieve a final roughness of less than 1 angstrom. Finally, the wafers may be exposed to a plasma process to controllably terminate the surface bonds with an oxygen and hydroxyl ions in order to create a surface amenable to the wafer bonding and the creation of a 2-degree electron gas at the diamond/AlGaN interface.

In illustrative embodiments, bandstructure engineering may be performed to guide the device design and optimize the heterostructure of the vertical PN diode. Bandstructure simulations may be performed to optimize the p-n junction between the p-type diamond substrate and the n-type AlGaN films. Illustrative embodiments consider graded-composition, polarization-engineered AlGaN layers as well as abrupt interfaces for minimizing barriers in the current flow, thus, enabling superior diode characteristics (i.e., ideality factor).

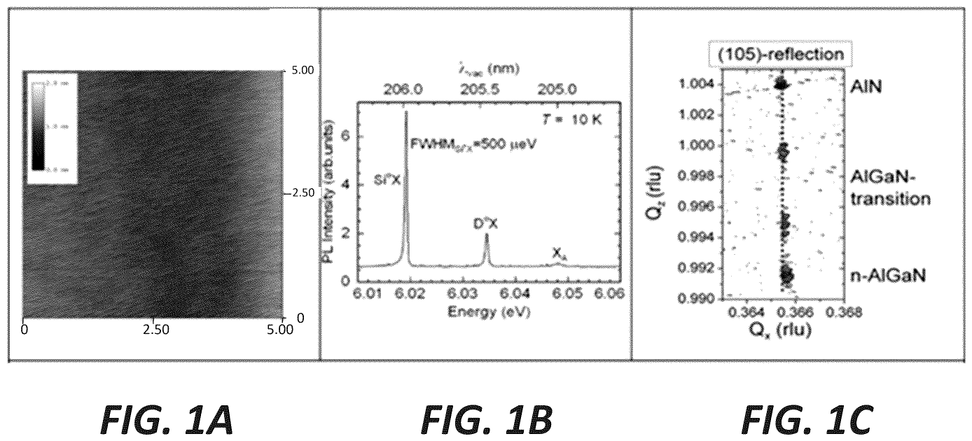

Those skilled in the art may use state-of-the-art cleanroom facilities to epitaxially grow and characterize high quality UWBG III-Nitride semiconductor materials, prepared for heterogeneous integration with the diamond substrates and subsequent device fabrication. Using MOVPE (Metal-organic Vapor Phase Epitaxy), the inventors demonstrated high quality homoepitaxial AlN on bulk AlN (e.g., see FIGS. 1A, 1B). This showed completely pseudomorphic n-type Al_{0.74}Ga_{0.26}N films exceeding 1 μm by deploying digital-alloy AlN/GaN SPSL transition layers Those in the art may build on this capability and optimize the semiconductor films for the application in PN diodes as described above. Comprehensive structural, electrical, and optical materials characterization (e.g., XRD, AFM, TEM, Hall, C-TLM, PL, etc.) can be used to quantify progress against the project metrics.

The fabrication techniques include laser lift-off, chemical-mechanical polishing, composition-selective wet etching or cantilevered thin film preparation and separation using selective area epitaxy.

Illustrative embodiments may use an advanced, high precision assembling and packaging tool, enabling heterogeneous integration of fragile, thin-film materials and chiplet devices onto various substrate types. This tool may be used for heterogeneously integrating n-AlGaN films and device sections onto the p-type diamond substrates. Direct bonding will be facilitated by the atomically smooth epitaxial surface of the AlGaN films and the ALE (atomic layer etching) prepared diamond substrates.

Illustrative fully vertically integrated R&D facilities offer the important processing tools for the proposed implementations, including dry/wet etching (e.g., RIE-ICP), deposition of metals and dielectrics (e.g., e-beam evaporation, sputtering, PECVD, etc.), plasma treatment, thermal annealing, etc. Strong emphasis in device fabrication preferably is given to optimizing contact performance, providing both low resistivity and high structural robustness for stable, high-power operation.

In addition to comprehensive materials characterization of specific heterostructure building blocks, illustrative embodiments may perform full device testing with complete vertical PN diamond/AlGaN diode test devices. Device testing will include IV characterization, leakage current, ideality factor determination, high voltage operation (>1 kV), and temperature-dependent characterization, etc.

FIGS. 1A, 1B, and 1C present experimental characterization data demonstrating the quality of III-N semiconductor materials grown by the inventors, which form the basis for the heterostructures used in the semiconductor devices described herein.

FIG. 1A shows an atomic force microscopy (AFM) image of homoepitaxial AlN grown on a bulk AlN substrate using metal-organic vapor phase epitaxy (MOVPE). The measured root-mean-square (rms) surface roughness is less than 0.15 nm, indicating an atomically smooth surface. This level of surface smoothness is relevant to the direct bonding processes described herein, as high-quality direct bonding between the III-N material and the diamond substrate benefits from surfaces having very low roughness (e.g., less than about 3 angstroms Ra, as described elsewhere herein). The ability to achieve sub-angstrom surface roughness on epitaxially grown III-N films demonstrates that the as-grown epitaxial surface may be suitable for direct bonding with minimal additional surface preparation.

The terms diamond body, diamond substrate, diamond wafer, and diamond may be used to refer generally to the diamond material forming part of the semiconductor device and are used interchangeably unless the context indicates otherwise. For example, diamond wafer may be used in the context of describing fabrication processes involving wafer-scale handling, while diamond body may be used in the context of describing the diamond material more broadly, including embodiments in which the diamond is produced by homoepitaxial growth rather than by slicing from a boule

FIG. 1B shows a low-temperature photoluminescence (PL) spectrum of grown AlN, measured at approximately 10 K. The spectrum shows donor-bound exciton emission lines (labeled D°X and Si°X) in the deep ultraviolet range near 6.01 to 6.05 eV, with a full width at half maximum (FWHM) of approximately 500 μeV. The narrowness of these emission lines indicates exceptionally high crystalline quality and low defect density in the AlN material. High crystalline quality in the III-N films is advantageous for the semiconductor devices described herein, as defects in the III-N material can degrade electrical performance, increase leakage current, and reduce the reliability of the p-n junction.

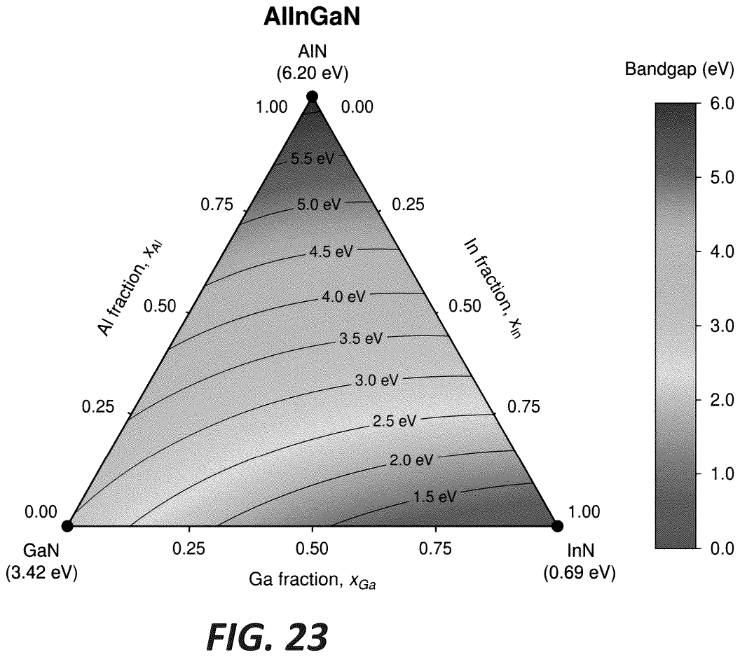

FIG. 1C shows an X-ray diffraction (XRD) reciprocal space map of an Al_{0.74}Ga_{0.26}N film grown on a bulk AlN substrate. The reciprocal space map confirms that the Al_{0.74}Ga_{0.26}N film is fully pseudomorphic, that is, the film has adopted the in-plane lattice constant of the underlying AlN substrate without relaxation. This is significant because pseudomorphic growth indicates that the AlGaN film is free of the misfit dislocations that arise from lattice relaxation, resulting in a high-quality crystalline layer suitable for device fabrication. The demonstrated ability to grow pseudomorphic AlGaN films exceeding 1 μm in thickness at aluminum fractions of 0.74 confirms the capability to produce device-quality III-N material in the ultra-wide bandgap composition range relevant to integration with diamond, as described with reference to FIG. 23. In various embodiments, similar epitaxial growth techniques may be used to produce the In(x)Al(y)Ga(1-x-y)N heterostructures described herein, including graded compositions and short-period superlattice transition layers, for subsequent direct bonding with the diamond substrate.

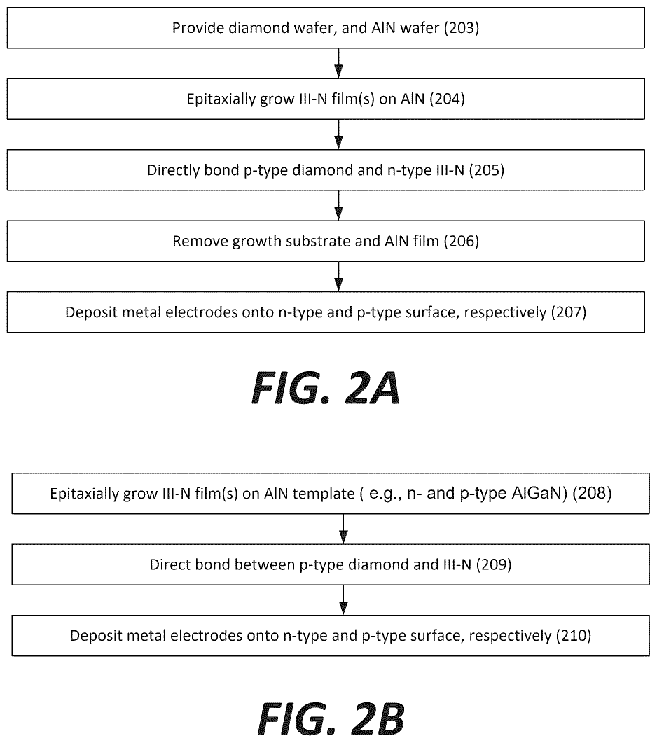

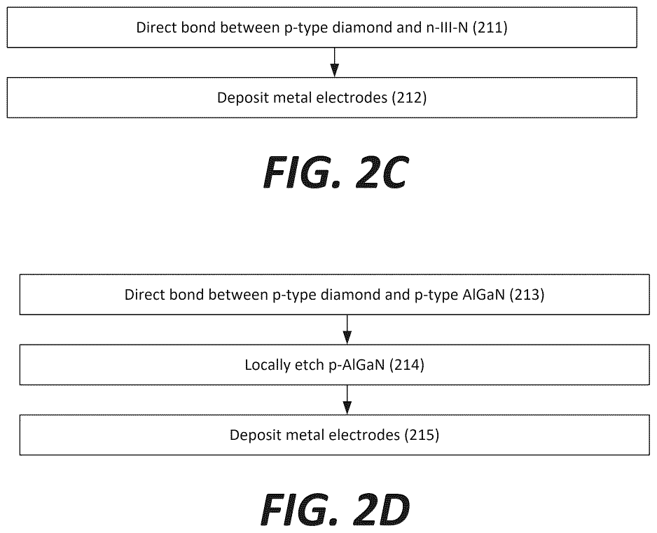

FIG. 2A schematically shows a process of producing a semiconductor device in accordance with illustrative embodiments of the invention. It should be noted that this method is substantially simplified from a longer process that may normally be used. Accordingly, the method shown in FIG. 2A may have many other steps that those skilled in the art likely would use. In addition, some of the steps may be performed in a different order than that shown, or at the same time. Furthermore, some of these steps may be optional in some embodiments. Accordingly, the process is merely exemplary of one process in accordance with illustrative embodiments of the invention. Those skilled in the art therefore can modify the process as appropriate.

Specifically, FIG. 2A shows a process of forming an ultra-wide bandgap III-N-to-diamond diode in accordance with illustrative embodiments. However, a variety of other semiconductor devices may be manufactured using a similar process. A III-N-to-diamond diode is a type of semiconductor device that combines Group III-nitride (III-N) materials, such as GaN (gallium nitride), AlN (aluminum nitride), or their alloys, with diamond as the other semiconductor layer. These diodes leverage the exceptional electrical, thermal, and mechanical properties of both material systems for specialized applications described herein and having the various advantages described herein.

The process begins at step 203, which provide (1) a diamond wafer, and (2) an In(x)Al(y)Ga(1-x-y)N wafer. For the sake of discussion, an AlN wafer is used. However, other embodiments may use any variety of In₍ₓ₎Al_{(y)}Ga_{(1-x-y)}N. Therefore, it should be understood that reference the AlN wafer is intended to apply to a variety of In₍ₓ₎Al_{(y)}Ga_{(1-x-y)}N materials. For example, other embodiments could use Al and Ga in equal proportions (e.g., 50% Al and 50% Ga). As yet another example, the In₍ₓ₎Al_{(y)}Ga_{(1-x-y)}N wafer may be a graded alloy. Thus, instead of having a uniform composition throughout, the proportions of the elements (e.g., aluminum, gallium, or indium in III-N alloys) are varied in a controlled manner. For example, in an alloy like In(x)Ga(1-x)N, the value of x might change from 0 at one end to 1 at the other, transitioning from pure GaN to pure InN. In addition to compositional grading, dopant concentrations can also be graded to create regions with tailored electrical properties. Additionally, or alternatively, the epitaxial InAlGaN may be a heterostructure comprising various alloy compositions of In, Al, Ga, and N

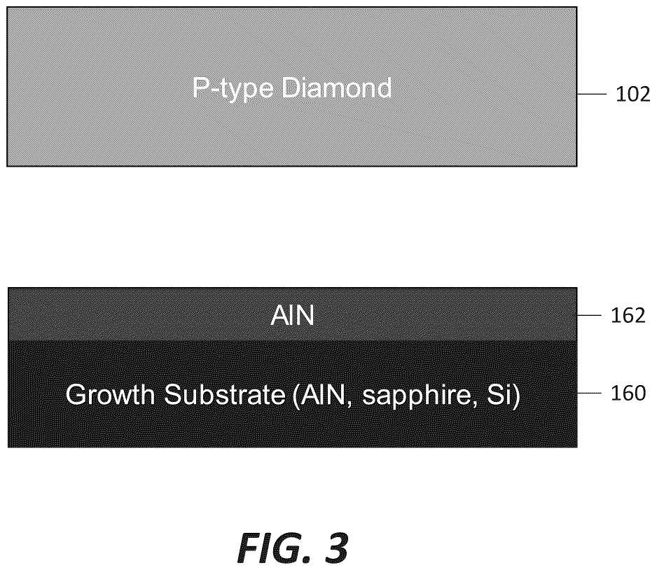

FIG. 3 schematically shows the diamond wafer 102 and the AlN wafer 162 in accordance with illustrative embodiments. The diamond wafer 102 may be a p-type diamond wafer 102. As known by those skilled in the art, the p-type diamond wafer 102 has been doped with impurities to introduce an excess of holes (positively charged carriers) as the primary means of electrical conduction. In its natural state, diamond is an excellent electrical insulator due to its wide bandgap of approximately 5.5 eV, which prevents the free movement of electrons. However, by doping diamond with specific elements, such as boron, the diamond can become a semiconductor. Boron atoms, when incorporated into the diamond lattice during growth (e.g., through chemical vapor deposition or high-pressure high-temperature methods), replace some carbon atoms and create energy levels slightly above the valence band. These energy levels make it easier for electrons to be excited from the valence band, leaving behind holes that act as the primary charge carriers. This doping process results in p-type conductivity. Generally, the diamond becomes p-type doped during the crystal growth process. Some embodiments may use post-growth doping.

The diamond wafer 102 may be produced, among other methods, by starting with boule growth, where a large single-crystal diamond structure is synthesized using Chemical Vapor Deposition (CVD) or High-Pressure High-Temperature (HPHT) techniques. The quality of the boule, including its crystallinity and defect density, determines the performance of the final wafers. After the diamond boule is grown, it is sliced into thin layers, or wafers, using advanced cutting techniques such as diamond wire saws or laser-based systems. This cutting process is preferably extremely accurate to ensure uniform wafer thickness and minimize damage to the crystal structure. In various embodiments, the diamond wafer 102 may have a thickness of between about 50 microns and about 650 microns.

In some embodiments, the diamond body includes homoepitaxially grown diamond. For example, a diamond layer 102 may be grown on a diamond seed, substrate, or wafer by chemical vapor deposition or another diamond growth process, such that the grown diamond layer 102 has crystallographic continuity with the underlying diamond material (e.g., single-crystal diamond). In some embodiments, the homoepitaxially grown diamond includes a doped region, such as a boron-doped p-type region. In some embodiments, the homoepitaxially grown diamond forms at least the portion of the diamond body adjacent the directly bonded III-nitride material.

After cutting, the diamond wafers 102 undergo polishing to smoothen their surfaces and remove any imperfections caused by the slicing process. Polishing advantageously creates surfaces with nanoscale smoothness, which is critical for applications in electronics and optics where surface quality directly impacts performance. Techniques like chemical-mechanical polishing (CMP) or plasma polishing may be employed to achieve the required surface finish. Additional treatments, such as doping or patterning, may be performed on the polished wafers.

The crystalline AlN (aluminum nitride) thin film, typically around 1 micron thick, is a highly ordered layer of aluminum nitride atoms deposited onto a growth substrate 160 (e.g., AlN, sapphire, Si) to create a structured material. In some embodiments, the crystalline AlN film 162 may be up to 5 microns, or up to 10 microns, thick. In various embodiments, the AlN film 162 may be between about 10 nanometers and about 3 microns, depending on the exact composition. Aluminum nitride is a wide bandgap semiconductor known for its excellent thermal conductivity, electrical insulation, chemical stability, and piezoelectric properties, making it suitable for high-performance devices like high-power transistors. The thin film is deposited using methods such as sputtering, chemical vapor deposition (CVD), or molecular beam epitaxy (MBE), which allow precise control over the film's thickness and crystalline quality.

The thin film is grown on and supported by a substrate, which acts as the foundation for the AlN layer and significantly impacts its quality and performance. Common substrates include AlN itself, which provides an ideal lattice match for minimizing defects and strain; sapphire (Al₂O₃), valued for its high thermal stability, optical transparency, and compatibility with AlN, though it introduces a slight lattice mismatch; and silicon (111), which offers a cost-effective solution for integration with existing silicon-based technologies despite having a significant lattice mismatch with AlN. Together, the crystalline AlN thin film and its substrate form a platform for use in illustrative embodiments.

The process proceeds to step 204, which epitaxially grows III-N film(s) on the AlN wafer 162. Preferably, the III-N film comprises In(x)Al(y)Ga(1-x-y)N. the material's composition is tunable by adjusting the values of x, y, and 1-x-y, representing the relative proportions of indium, aluminum, and gallium, respectively. where x and y vary within the range of 0-100, inclusive. Thus, as an example, various embodiments may not include Indium. In graded alloys, certain points can have 0%. Accordingly, the use of n-AlGaN 142 is provided as an example.

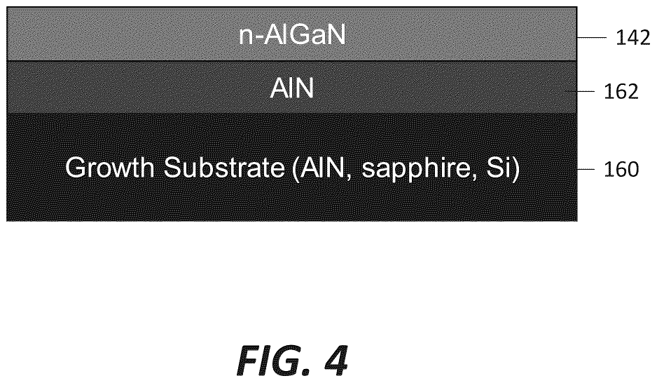

FIG. 4 schematically shows a III-N film 142 epitaxially grown on the AlN wafer 162 in accordance with illustrative embodiments. In various embodiments, the III-N film(s) are n-type doped. For example, n-type AlGaN may be grown on the AlN wafer 162. The n-type AlGaN is doped to introduce an excess of free electrons as charge carrier. This may be achieved by incorporating donor impurities, such as silicon (Si) or oxygen (O), into the crystal structure during growth. The proportion of aluminum (Al) and gallium (Ga) in the alloy can be adjusted to tune the material's properties, such as its bandgap, lattice constant, and electrical conductivity.

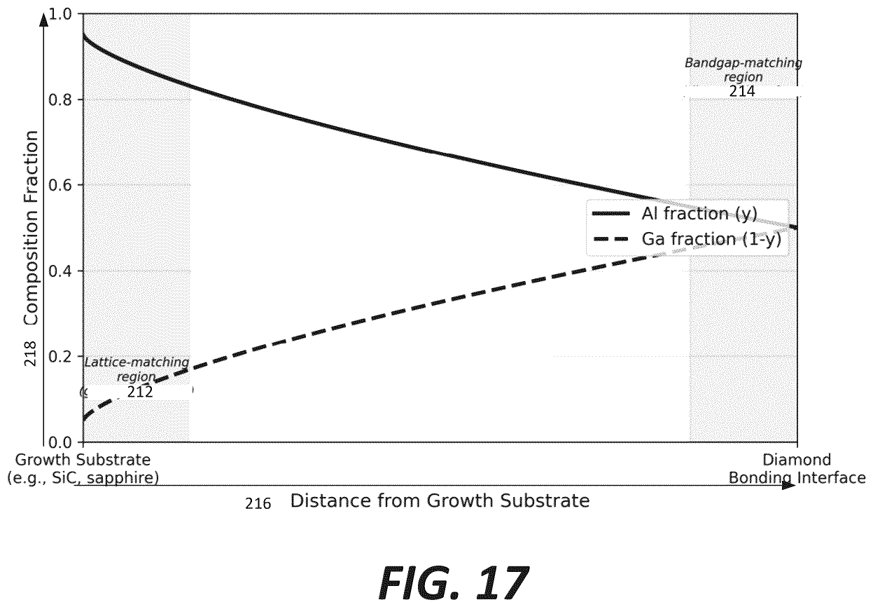

In various embodiments (e.g., as shown in FIG. 17), the III-nitride body 142 may include a compositional grading profile in which a first region adjacent the growth substrate 160 is selected to facilitate epitaxial growth (e.g., lattice compatibility), while a second region nearer the diamond bonding interface is selected to provide a desired bandgap and/or band alignment relative to the diamond. The composition may vary continuously or stepwise between these regions. The N-type AlGaN may be grown on AlN substrates using, for example, techniques like molecular beam epitaxy (MBE) or metal-organic chemical vapor deposition (MOCVD). These processes ensure high-quality epitaxial growth, where the AlGaN layer aligns with the crystalline structure of the AlN substrate. In various embodiments, the growth begins with surface preparation of the AlN substrate to ensure smoothness and cleanliness, followed by depositing the AlGaN layer. During growth, the ratio of aluminum to gallium is carefully controlled by adjusting the input of precursor gases, such as trimethylaluminum (TMA) for aluminum and trimethylgallium (TMG) for gallium. Dopants like silane (SiH₄) may be introduced to achieve n-type conductivity.

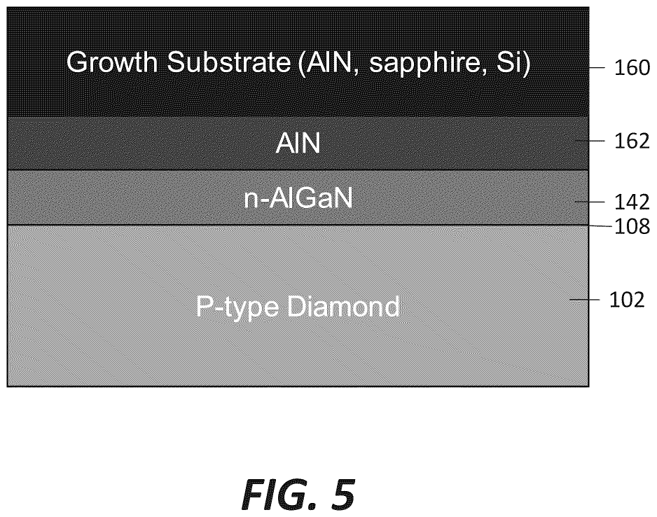

At step 205, a direct bond 108 is provided between the p-type diamond 102 and n-type III-N material 142. FIG. 5 schematically shows the p-type diamond 102 and the n-type III-N 142 directly bonded. Various embodiments directly bond the diamond and the III-n using plasma assisted bonding, low-temperature wafer bonding, and/or surface activated bonding, among other techniques. Various embodiments wafer bond the InAlGaN heterostructure on the diamond substrate 102 by disposing a surface of the heterostructure against the polished surface of the diamond substrate 102, applying pressure to enhance contact between the surfaces, and applying temperature to induce interaction of surface atoms. For example, a pressure of between about 0.1 MPa to about 1 MPa (or about 1 to 10 atmospheres) may be used for about 30 minutes to about 60 minutes. Additionally, a temperature of between about 300 C and about 500 C may be used for about 30 minutes to about 60 minutes.

In various embodiments, a direct bond 108 refers to bonding between the diamond 102 and the III-nitride material 142 in the absence of an intervening adhesive or filler layer. In some embodiments, the directly bonded interface is formed by bringing prepared and/or activated surfaces of the diamond 102 and the III-nitride material 142 into contact, optionally under vacuum or reduced pressure and optionally with applied pressure and/or heat. In some embodiments, the directly bonded interface 108 is substantially free of polymeric glue, solder, thick dielectric filler, or other extraneous bonding medium separating the bonded semiconductor bodies.

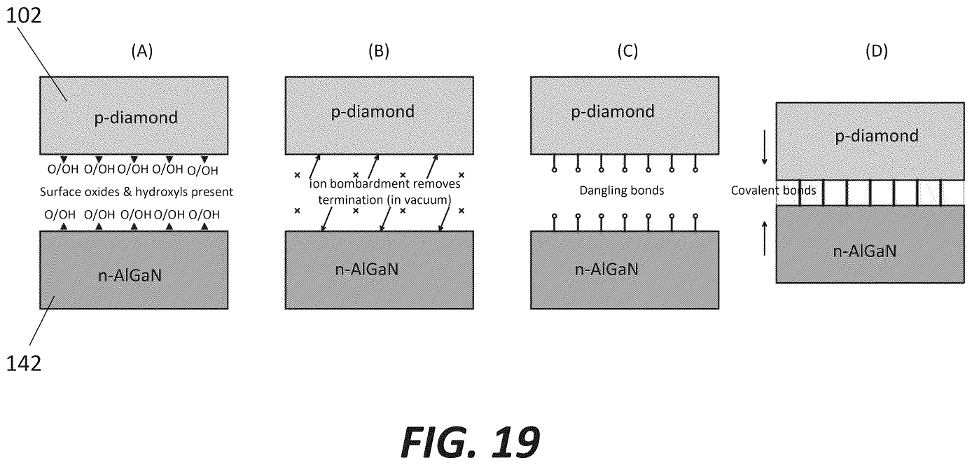

Some embodiments may include an extremely thin native or process-induced interfacial region, such as a region resulting from activation or atomic rearrangement at the bonded interface. Such embodiments may still be regarded as directly bonded so long as the bond is formed by direct interaction of the diamond surface and the III-nitride surface rather than by an intervening adhesive or filler material. For example, FIG. 19 described further below schematically illustrates one example of a direct bonding process.

The interface between the n-type and p-type materials should be of high quality with minimal defects to ensure proper junction behavior. Poor bonding can result in high interface resistance or the presence of traps, which can degrade the diode's performance. Given the significant band differences between diamond and III-N, various embodiments adjust the ratio of atoms to create a match of band gap energies (i.e., adjust the III-nitride composition to provide a desired bandgap and/or band alignment relative to the diamond) to ensure proper conduction. In some other embodiments, the InAlGaN may be an epitaxial layer to achieve the best crystal quality.

In some embodiments, the surfaces to be bonded are prepared to have very low roughness so that intimate contact can be achieved across the intended bonding area. For example, the bonding surface of the diamond body (e.g., the p-type diamond 102 surface that will form the p-n junction 106 interface) and the bonding surface of the III-nitride body 142 (e.g., the n-type AlGaN surface or, in embodiments having a p-type AlGaN layer, the p-type AlGaN surface) may each be polished and/or plasma treated to provide a surface roughness of less than about 3 angstroms Ra. In other embodiments, one or both bonding surfaces may have a roughness of less than about 5 angstroms Ra, less than about 1 angstrom Ra, or another suitably low value.

In addition to local smoothness, global flatness of the surfaces may also be controlled. This may be particularly useful where the bonded bodies are wafer-scale bodies that are to be bonded over a substantial area, rather than small isolated chiplets. In such embodiments, both local surface roughness and overall wafer flatness may affect bond quality. Accordingly, one or both bodies may be processed to satisfy a selected total thickness variation (TTV), bow, warp, or flatness criterion appropriate for the bonding area and wafer dimensions. For example, for a 25 mm diameter diamond wafer 102, a TTV of less than about 3 micron may be suitable for achieving high-quality direct bonding across the full wafer area. For larger diameter wafers (e.g., 50 mm or greater), the acceptable TTV may scale with the wafer diameter, as larger wafers may flex to accommodate modest thickness variations that would be unacceptable in a smaller, more rigid body. In various embodiments, the TTV may be less than about 5 microns, less than about 2 microns, or less than about 1 micron, depending on the wafer diameter, material stiffness, and bonding conditions. In various embodiments, the bonded structure may be formed by directly bonding bodies having substantially corresponding lateral dimensions, such that the bonded bodies together define a composite wafer or wafer-like body.

In some embodiments, the direct bond is performed at wafer scale. For example, a diamond wafer 102 and a III-nitride-bearing wafer may be aligned and bonded over substantially their full opposed major surfaces, thereby producing a bonded composite structure that may subsequently be processed as a unitary wafer. This may facilitate subsequent thinning, substrate removal, lithography, contact formation, singulation, or other semiconductor processing operations.

In some embodiments, the bonded wafers have substantially the same diameter or substantially the same lateral dimensions. For example, a 25 mm p-type diamond wafer 102 may be directly bonded to a 25 mm III-nitride wafer 142 bearing an n-type AlGaN film 142, forming a composite wafer that can be processed using standard semiconductor fabrication equipment. In other embodiments, the bonded bodies may have different dimensions, such as where a smaller III-nitride chiplet or device section is bonded to a larger diamond substrate 102 or carrier. Illustrative embodiments are therefore not limited to a particular bonding footprint. However, where wafer-scale direct bonding is used, both local smoothness and global flatness may be important to obtaining a high-quality bond across the full bonding area.

In various embodiments, the composition of the III-nitride material is selected to provide a desired electronic relationship with the diamond, such as a desired bandgap, band alignment, conduction-band offset, valence-band offset, electron affinity relationship, carrier injection property, depletion behavior, electric-field distribution, or breakdown characteristic. Thus, while some embodiments may employ III-nitride compositions having a bandgap that approaches or corresponds to a bandgap value of diamond over a selected range, other embodiments instead or additionally select the III-nitride composition to provide a desired interfacial electronic structure or junction behavior at the bonded diamond/III-nitride interface.

In some embodiments, the III-nitride composition is configured to facilitate electron transport, hole transport, reduced interfacial barrier height, improved rectification, increased breakdown voltage, reduced leakage current, improved ideality factor, or combinations thereof. Accordingly, references herein to “matching” a bandgap should be understood more broadly as selecting and/or engineering one or more III-nitride compositions to provide a desired device behavior relative to diamond.

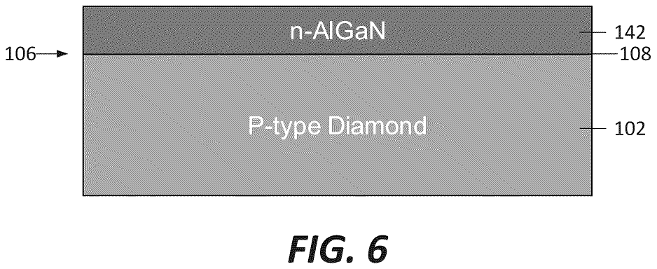

At step 206, the process removes the growth substrate 160 and the AlN film 162. FIG. 6 schematically shows the structure with the growth substrate 160 and AlN film 162 removed in accordance with illustrative embodiments. As shown, the diamond layer 102 and the n-AlGaN 142 remain bonded. The InAlGaN heterostructure may be removed from its substrate using techniques such as laser lift-off, selective wet chemical etching, ion-implant smart cut peeling, or spalling to enable its integration into advanced devices or to transfer it onto a different substrate. In various embodiments, the removal of the InAlGaN heterostructure from its original substrate typically happens after the InAlGaN is bonded to diamond. This approach ensures that the fragile InAlGaN layer is supported during the removal process, preventing damage or deformation.

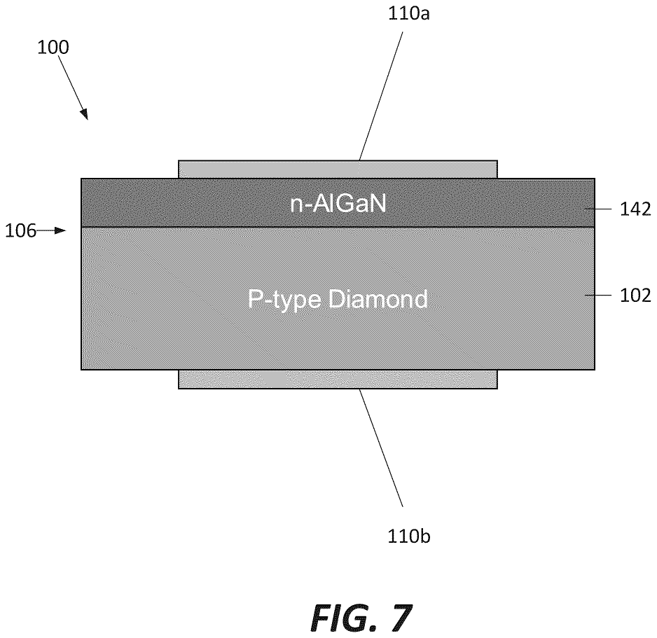

At step 207, metal electrodes 110 are deposited onto the n-type and p-type surface, respectively. FIG. 7 schematically shows a p-n junction 106 formed by a p-type layer and an n-type layer having metal electrodes 110 in accordance with illustrative embodiments. In various embodiments, for the p-type side, the metal electrodes may be formed of platinum or gold, among other things. For the n-type side, the metals may be formed from aluminum or titanium, among other things.

Accordingly, as shown, the process of FIG. 2A provides a semiconductor structure that may function as a switch. The switch includes a synthetic doped diamond substrate 102, and an In₍ₓ₎Al_{(y)}Ga_{(1-x-y)}N layer 142 disposed on a surface of said diamond substrate 102 (e.g., n-AlGaN 142, where x=0). In various embodiments, a layer or body disposed on a substrate or other layer includes a layer or body positioned over, supported by, or bonded to that substrate or layer, and does not require that the layer or body be grown in situ on the underlying structure. Thus, in various embodiments, the III-nitride body 142 is formed on a separate growth template and subsequently transferred and directly bonded to the diamond substrate 102.

In various embodiments, the diamond substrate 102 is synthetic (i.e., grown), as natural diamond is unlikely to reach the concentration of dopant advantageous for various embodiments. In various embodiments, the In(x)Al(y)Ga(1-x-y)N layer 142 may be grown epitaxially. Electrons flow from the n-side (where they are the majority carriers) toward the p-side, across the junction. Accordingly, a p-n junction 106 is formed between the p-layer and the n-layer such that current flows along a direction perpendicular to the surface of the diamond substrate 102. The diamond, In(x)Al(y)Ga(1-x-y)N layer 142, and p-n junction 106 together may form a switch. The metal contacts may be in electrical contact with the diamond substrate 102 and with the In(x)Al(y)Ga(1-x-y)N layer 142, wherein the switch is configured to turn on when a voltage bias is applied across said p-n junction 106.

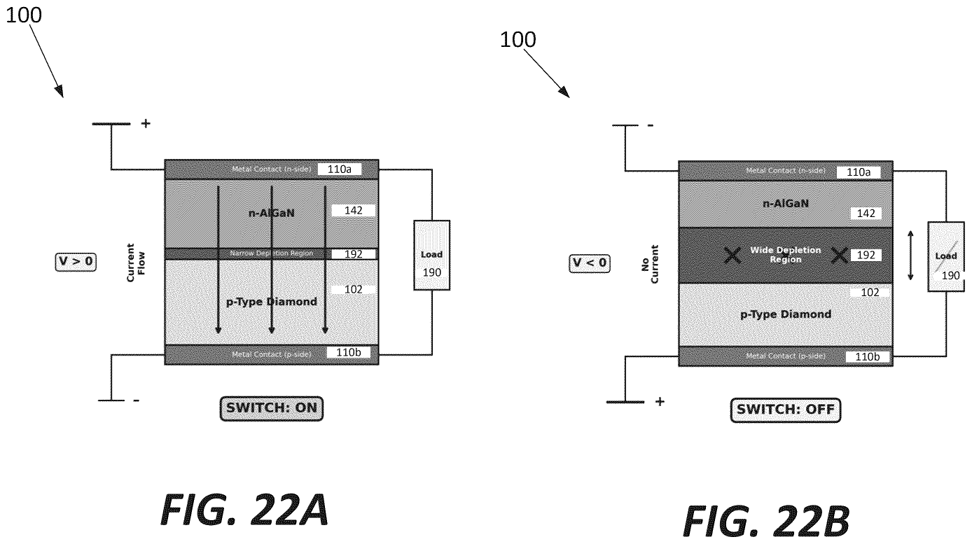

In various embodiments, a switch includes a p-type diamond layer 102 directly bonded to an n-type In(x)Al(y)Ga(1-x-y)N layer 142 that operates as a p-n junction 106 diode-based switch, leveraging the unique properties of both materials. The p-n junction 106 formed at the interface between the p-type diamond 102 and the n-type III-N alloy 142 (In(x)Al(y)Ga(1-x-y)N) serves as the active switching element. In the forward bias mode, when a positive voltage is applied to the p-type diamond layer 102 (relative to the n-type III-N layer), the built-in electric field at the p-n junction 106 is overcome, allowing holes from the diamond to combine with electrons from the III-N layer. This creates a conductive path, enabling current to flow through the device. Conversely, in the reverse bias mode, when the polarity is reversed, the depletion region 192 at the junction widens, effectively blocking current flow and putting the switch in the “off” state (e.g., see FIGS. 22A-22B).

This switching mechanism is highly efficient due to the combined properties of the materials. The p-type diamond layer 102 provides exceptional thermal conductivity and high carrier mobility, which ensures efficient heat dissipation and fast switching speeds even in high-power applications. The n-type In(x)Al(y)Ga(1-x-y)N layer 142, with its tunable bandgap and strong electronic properties, enables the device to operate under high voltages and frequencies. The direct bonding of the two materials ensures a high-quality junction 106 with minimal interface defects, which is advantageous for the reliable operation of the switch. Such a device can operate in extreme environments, handling high power and temperatures, making it ideal for advanced power electronics, RF devices, and applications in harsh industrial or aerospace conditions.

Some embodiments may thermally anneal after wafer bonding is to enhance the quality and functionality of the bonded interface by inducing atomic diffusion across the boundary. This diffusion helps improve mechanical, electrical, and thermal properties at the interface, which is especially important in high-performance devices. In devices like p-n junctions 106 with bonded layers of p-type diamond 102 and n-type In(x)Al(y)Ga(1-x-y)N, thermal annealing can promote atomic diffusion between diamond and III-N materials, creating a strong and low-resistance interface. It may also improve thermal management by enhancing heat transfer across the junction. Furthermore, annealing may ensure reliable operation at high voltages and temperatures.

Additionally, some embodiments may plasma treat one or both of the surfaces prior to bonding. In the bonding of p-type diamond 102 and n-type In(x)Al(y)Ga(1-x-y)N layers 142, plasma activation of one or both surfaces can advantageously remove native oxides and impurities that hinder bonding, introduce reactive sites for strong covalent bonding during annealing, and enable bonding at lower temperatures, reducing thermal stress due to lattice mismatch.

FIG. 2B schematically shows another embodiment of a process of producing a semiconductor device 100 in accordance with illustrative embodiments of the invention. It should be noted that this method is substantially simplified from a longer process that may normally be used. Accordingly, the method shown in FIG. 2B may have many other steps that those skilled in the art likely would use. In addition, some of the steps may be performed in a different order than that shown, or at the same time. Furthermore, some of these steps may be optional in some embodiments. Accordingly, the process is merely exemplary of one process in accordance with illustrative embodiments of the invention. Those skilled in the art therefore can modify the process as appropriate.

Specifically, FIG. 2B shows a process of forming an ultra-wide bandgap III-N-to-diamond diode in accordance with illustrative embodiments. It should be understood that many of the steps of FIG. 2A may also apply to FIG. 2B, and therefore, are not repeated here. Similarly, many of the steps of FIG. 2B may also be used in FIG. 2A.

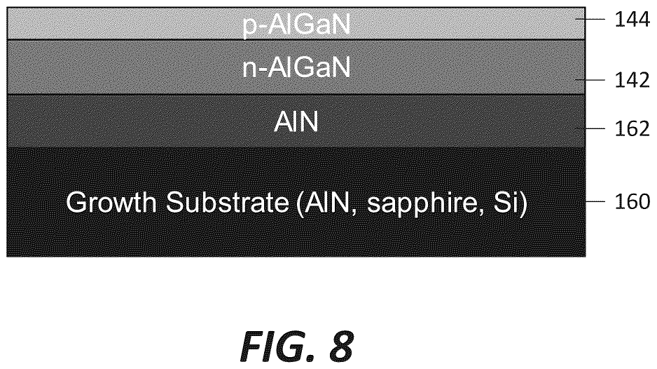

At step 208, a III-N film (e.g., n- and p-type In(x)Al(y)Ga(1-x-y)N) is epitaxially grown on a template (e.g., AlN). FIG. 8 schematically shows epitaxially grow III-N film on AlN template. As shown, an n-type AlGaN 142 may be grown over the AlN layer 162. Subsequently, a p-type AlGaN 144 layer may be grown on the n-type AlGaN 142. These two layers ultimately form the p-n junction 106 of the semiconductor device 100.

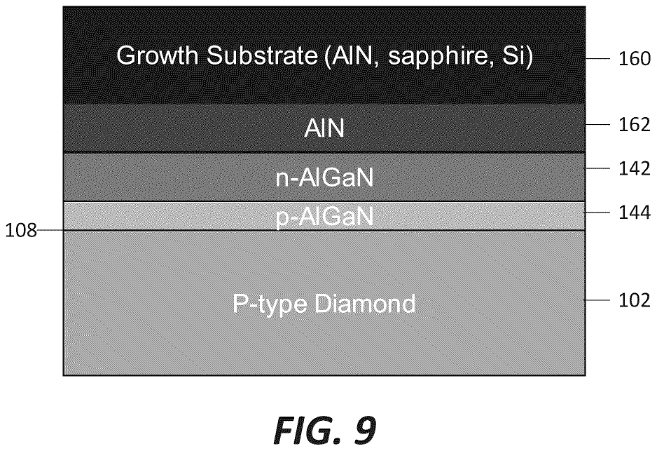

At step 209, the diamond layer 102 is directly bonded with the III-N layer. FIG. 9 schematically shows the diamond layer 102 bonded with the III-N layer. In this example, the p-type AlGaN 144 is bonded with a p-type diamond.

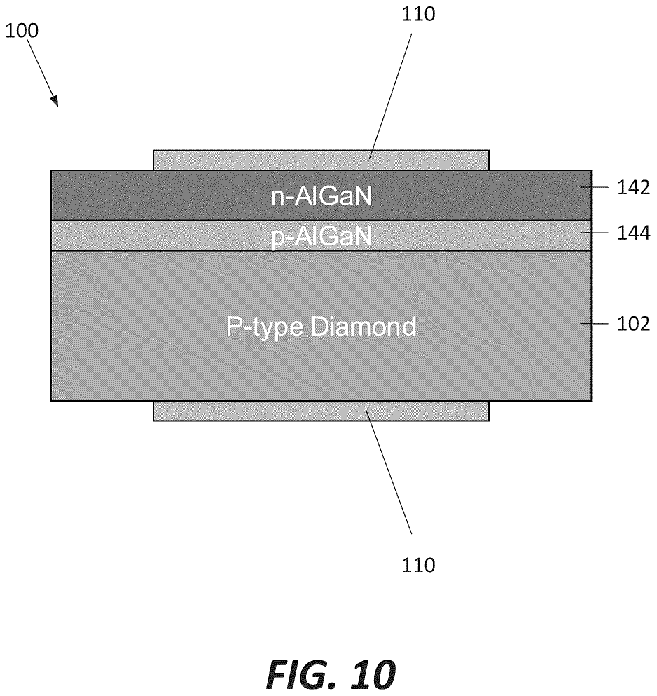

At step 210, metal electrodes 110 are deposited onto the n-type and p-type surface, respectively. FIG. 10 schematically shows metal electrodes 110 deposited onto n-type and p-type surface.

FIG. 2C schematically shows another embodiment of a process of producing a semiconductor device 100 in accordance with illustrative embodiments of the invention. It should be noted that this method is substantially simplified from a longer process that may normally be used. Accordingly, the method shown in FIG. 2C may have many other steps that those skilled in the art likely would use. In addition, some of the steps may be performed in a different order than that shown, or at the same time. Furthermore, some of these steps may be optional in some embodiments. Accordingly, the process is merely exemplary of one process in accordance with illustrative embodiments of the invention. Those skilled in the art therefore can modify the process as appropriate.

Specifically, FIG. 2C shows a process of forming an ultra-wide bandgap III-N-to-diamond diode in accordance with illustrative embodiments. It should be understood that many of the steps of FIGS. 2A and 2B may also apply to FIG. 2C, and therefore, are not repeated here. Similarly, many of the steps of FIG. 2C may also be used in the processes of FIGS. 2A and 2B.

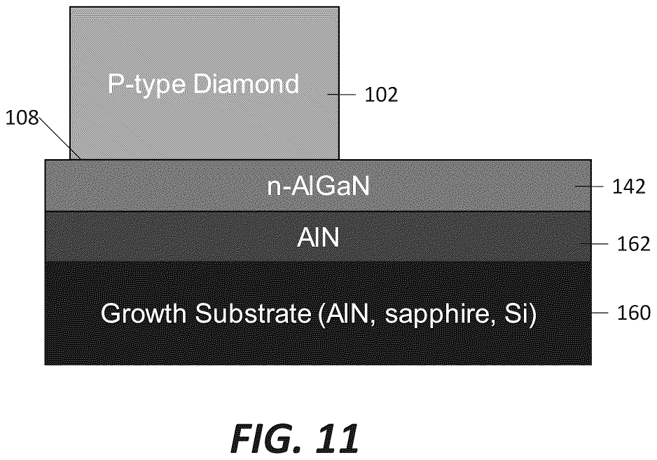

The process begins at step 211, which directly bonds a p-type diamond 102 and a n-type-III-N layer. FIG. 11 schematically shows a diamond layer 102 bonded to a In(x)Al(y)Ga(1-x-y)N layer 142. A p-n junction 106 is formed between the p-type diamond 102 and the n-type AlGaN.

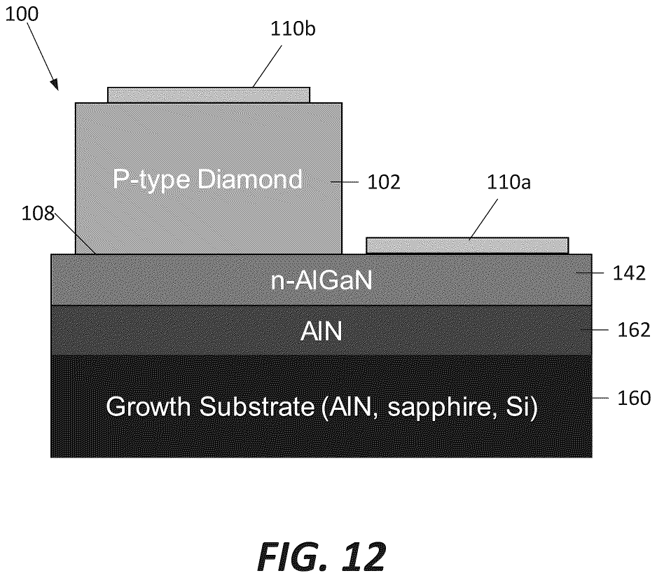

At step 212, metal electrodes 110 are deposited onto the p-type diamond 102 and the n-type AlGaN 142. FIG. 12 schematically shows metal electrodes 110 deposited on the semiconductor device 100 in accordance with illustrative embodiments. The semiconductor device may then function as a switch 100, as described previously.

FIG. 2D shows yet another process of forming a semiconductor device 100 from a diamond layer 102 and a In(x)Al(y)Ga(1-x-y)N layer 142 in accordance with illustrative embodiments. It should be noted that this method is substantially simplified from a longer process that may normally be used. Accordingly, the method shown in FIG. 2D may have many other steps that those skilled in the art likely would use. In addition, some of the steps may be performed in a different order than that shown, or at the same time. Furthermore, some of these steps may be optional in some embodiments. Accordingly, the process is merely exemplary of one process in accordance with illustrative embodiments of the invention. Those skilled in the art therefore can modify the process as appropriate. Specifically, FIG. 2D shows a process of forming an ultra-wide bandgap III-N-to-diamond diode in accordance with illustrative embodiments. It should be understood that many of the steps of FIGS. 2A-2C may also apply to FIG. 2D, and therefore, are not repeated here. Similarly, many of the steps of FIG. 2D may also be used in the processes of FIGS. 2A-2C.

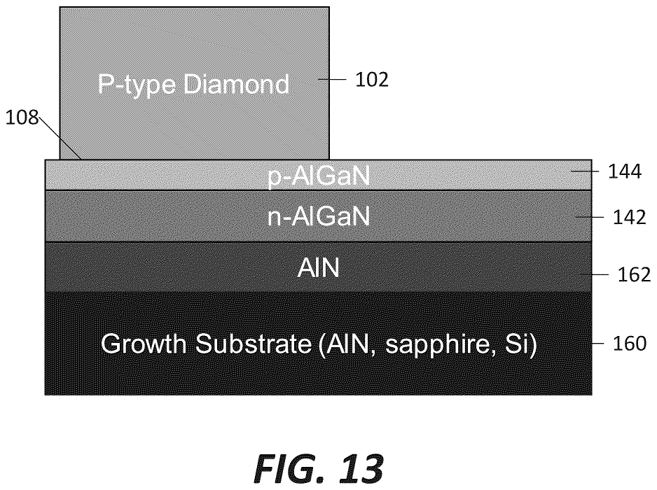

The process begins at step 213, which directly bonds a p-type diamond 102 and a p-type AlGaN. This process is very similar to step 211, except an additional p-type AlGaN layer 144 is grown on an n-type AlGaN layer 142. FIG. 13 schematically shows a p-type diamond 102 bonded to a p-type AlGaN 144. In this embodiment, the p-n junction 106 is formed between the p-type AlGaN 144 and the n-type AlGaN 142.

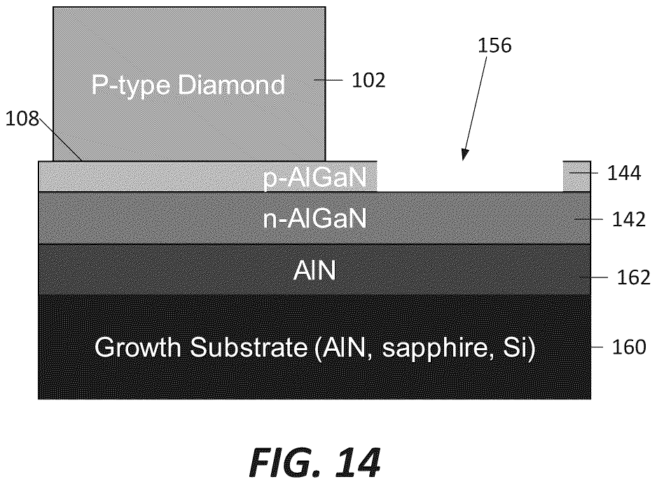

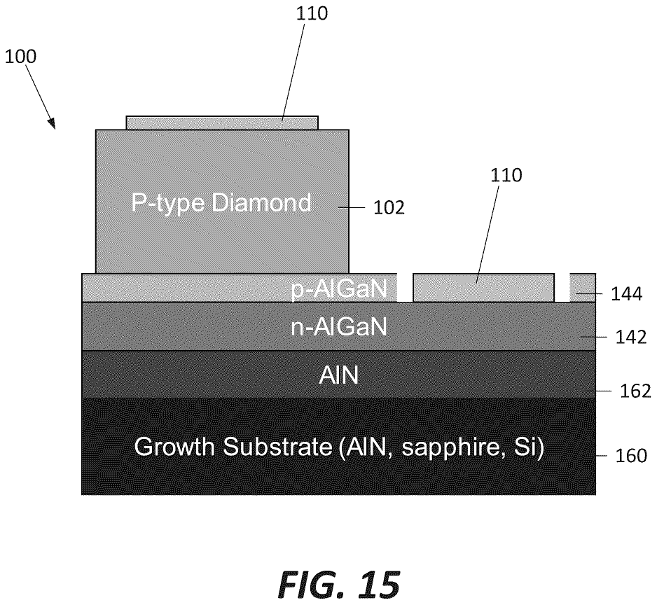

At step 214, the p-type AlGaN 144 is locally etched. FIG. 14 schematically shows the p-type AlGaN locally etched in accordance with illustrative embodiments. At step 215, metal electrodes 110 may be deposited onto the p-type conductor (e.g., the diamond) and the n-type conductor (e.g., in the etched portion 156). FIG. 15 schematically shows metal electrodes 110 deposited on the diamond 102 and n-type AlGaN 142.

The process then comes to an end.

It should be apparent that in various embodiments the p-n junction 106 is advantageously at the diamond-In(x)Al(y)Ga(1-x-y)N interface (e.g., FIG. 6, FIG. 14). To that end, the diamond 102 may be p-type doped and the In(x)Al(y)Ga(1-x-y)N may be n-type doped. However, in some other embodiments, the p-n junction 106 may be formed by the interface between two differently doped In(x)Al(y)Ga(1-x-y)N layers 142 (e.g., FIG. 9, FIG. 12). Among other things, the p-type doping element may be boron, magnesium, zinc, and/or beryllium, and the n-type doping elements may be silicon, germanium, oxygen, phosphorous and/or nitrogen.

In various embodiments, the diamond provides the p-type region, for example through boron doping. Diamond is attractive for high-power and high-frequency semiconductor applications because of its large bandgap and very high thermal conductivity. However, in many implementations, formation of a practical complementary conductivity region using diamond alone, particularly an effective n-type diamond 102 region, may be challenging. Accordingly, various embodiments use a heterogeneous diamond/III-nitride structure to provide a practical junction architecture while preserving the thermal advantages of diamond.

In various embodiments, the III-nitride body 142 may include one or more regions of selected conductivity type, such as an n-type region, a p-type region, an intrinsic region, or combinations thereof. The III-nitride body 142 may include an n-type region, for example an n-type AlGaN region, that cooperates with the p-type diamond 102 to form a junction. In some embodiments, the III-nitride body 142 may also include a p-type region, for example where the principal p-n junction 106 is formed within the III-nitride body.

Furthermore, various embodiments may include an intrinsic, un-doped film between the p-type and n-type region, forming a p-i-n structure. The intrinsic layer does not have free charge carriers (electrons or holes) and thus serves as an insulating or depletion layer. This extends the depletion region 192 across the intrinsic layer, separating the p-type and n-type regions. In various embodiments, the undoped layer preferably has a thickness of 50 microns or less. In most use cases, the undoped layer would be considerably thinner, on the order of 0.1 microns to 1 micron. However, there are applications can could be thicker, up to 5 microns, for example. Undesirably, an insulation layer that is too thick could increase the resistance and reduce current flow under forward bias. The increased depletion width can slow down carrier transit, affecting device speed in applications like RF or high-frequency switches.

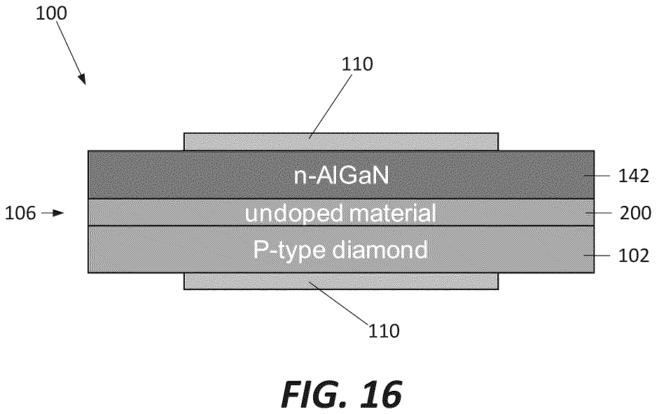

FIG. 16 schematically shows a p-i-n junction 106 in accordance with illustrative embodiments. In some embodiments, the p-i-n junction 106 may be formed by a CVD grown diamond that is p-type doped and also has an undoped region 200. The process to form this diamond is similar to the process described with reference to FIG. 6, except the diamond wafer 102 has an undoped portion 200. Additionally or alternatively, the undoped material 200 may include one or more of SiO2, Al2O3, AlN, AlGaN, SiN, and/or HfO2.

As described previously, one or more of the layers of the In₍ₓ₎Al_{(y)}Ga_{(1-x-y)}N may be graded. Thus, instead of having a uniform composition throughout, the proportions of the elements (e.g., aluminum, gallium, or indium in III-N alloys) are varied in a controlled manner. For example, in a p-n junction 106 for a semiconductor switch 100, the p-doping element may be boron, and the n-doping may be a graded aluminum (Al) composition in In(x)Al(y)Ga(1-x-y)N. The p-type region, doped with boron, introduces holes as majority carriers, creating a robust p-type layer with excellent thermal conductivity and mechanical stability. On the n-side, the aluminum composition may be the graded In(x)Al(y)Ga(1-x-y)N layer 142 increases gradually along the growth direction, starting with a low Al fraction at the interface and transitioning to a high Al fraction at the outer surface. This compositional grading widens the bandgap progressively, generating a built-in electric field that facilitates efficient carrier transport across the junction and reduces carrier recombination. Additionally, the grading minimizes lattice mismatch and strain, ensuring a high-quality interface between the p-type and n-type layers. The structure is grown on an Al-polar substrate, which enhances polarization effects, creating an additional electric field that supports the efficient separation of charge carriers and improves switching performance. In a similar manner, the graded In(x)Al(y)Ga(1-x-y)N layer 142 increases gradually along the growth direction, starting with a low Ga fraction at the interface and transitioning to a high Ga fraction at the outer surface.

Thus, in some embodiments, the III-nitride body 142 is configured such that a first region nearer the original growth template is selected with regard to epitaxial growth considerations, while a second region nearer the diamond-bonding interface is selected with regard to electronic or thermal device considerations. The grading may be continuous, stepwise, quasi-continuous, or formed using a superlattice or short-period superlattice structure. In some embodiments, the graded material includes AlGaN. In other embodiments, the graded material includes InAlGaN, AlN/GaN superlattices, or other III-nitride compositions.

As another example, the semiconductor device 100 may operate as a semiconductor switch 100 designed for a high-power inverter in electric vehicles. The p-type region is a boron-doped diamond layer 102, chosen for its superior thermal conductivity, which efficiently dissipates heat generated during high-speed switching operations. The n-type region may include a graded In(x)Al(y)Ga(1-x-y)N layer 142, where the aluminum content increases from 10% at the p-n junction 106 to 50% at the surface. This grading creates a strong bandgap gradient, supporting high breakdown voltages and efficient current flow under forward bias. The device may be fabricated on an Al-polar silicon carbide (SiC) substrate, enabling excellent crystal alignment and amplifying the polarization-induced electric fields. In operation, when a control signal applies forward bias, the depletion region 192 narrows, allowing current to flow. In reverse bias, the graded structure ensures that the depletion region 192 widens significantly, blocking current flow and providing excellent reverse-blocking performance. This design allows the switch to handle high voltages and currents efficiently while operating at high frequencies, making it ideal for power electronics applications where performance and durability are critical. For example, advantageously, the switch may be configured to receive an applied voltage of greater than 5 KV without breakdown.

Although shown as p-type doped, it should be understood that in various embodiments the diamond layer 102 may be n-type doped, and the In(x)Al(y)Ga(1-x-y)N layer 142 may be p-type doped. A person of skill in the art understands that the examples shown may be reversed to achieve a similar p-n junction 106.

In some embodiments, n-type or p-type doping may additionally, or alternatively, be achieved via polarization doping. Polarization doping is a mechanism in III-N semiconductors that leverages the intrinsic polarization properties of materials to induce free charge carriers (electrons or holes) without the need for traditional dopant atoms. This phenomenon occurs due to the strong spontaneous polarization and piezoelectric polarization inherent in III-N materials like GaN, AlN, and their alloys (e.g., InAlGaN). By engineering compositional gradients in the material, polarization-induced charges can be generated, effectively creating n-type or p-type regions.

For example, the InAlGaN structure can be formed to induce n-type or p-type conductivity through compositional grading, which modifies the polarization across the material. In some embodiments, by gradually varying the proportions of indium (In), aluminum (Al), and gallium (Ga) in the In(x)Al(y)Ga(1-x-y)N alloy, the spontaneous and piezoelectric polarization in the material changes. For example, a low Al-content region to high Al-content region creates a polarization gradient due to the increasing spontaneous polarization of AlN relative to GaN or InN.

Grading the Al composition from low to high in the growth direction (e.g., GaN to AlN) results in negative bound charges at the graded interface. These bound charges attract free electrons, inducing n-type conductivity in the graded region.

As another example, grading the Al composition from high to low in the growth direction (e.g., AlN to GaN) results in positive bound charges at the graded interface. These bound charges attract free holes, inducing p-type conductivity in the graded region.

In some embodiments, the p-n junction 106 may form within a layer of the heterostructure rather than as an interface between two layers. A layer of In(x)Al(y)Ga(1-x-y)N can be doped during the growth process to form the p-n junction 106. Such doping may occur by introducing different impurities during the growth process (e.g., Mg or Zinc during the p-type growth, and Si or O during the n-type growth). Additionally, or alternatively, this may be achieved using a graded composition, or polarization effects, as described previously.

In various embodiments, the heterostructure includes epitaxial layers with bandgaps in the range between 4 eV and 6.2 eV. The heterostructure may have repeating layers, such that a superlattice (e.g., short period superlattice) is formed.

FIG. 17 graphically shows an example compositional grading profile of an Al(y)Ga(1-y)N layer in accordance with illustrative embodiments. The horizontal axis represents distance 216 from the growth substrate 160 (e.g., distance from the SiC, sapphire, or GaN) to the diamond 102 bonding interface. The vertical axis represents the composition fraction 218 of aluminum (solid line) and gallium (dashed line), respectively.

In various embodiments, one or more III-nitride layers are compositionally graded. The grading may be selected to provide one or more of improved epitaxial growth, reduced defect density, strain management, polarization engineering, carrier transport control, barrier engineering, depletion-region shaping, leakage reduction, breakdown enhancement, or interface optimization. In some embodiments, a first portion of the graded structure is selected with regard to compatibility with the original growth template, while a second portion of the graded structure nearer the bonded interface is selected with regard to desired electronic behavior relative to diamond.

As shown, in the region proximate to the growth substrate 160, the aluminum fraction is high (e.g., approximately 0.95) to achieve lattice matching with the growth substrate 160, thereby promoting single-crystal quality during epitaxial growth. As the distance from the growth substrate 160 increases toward the diamond bonding interface 108, the aluminum fraction decreases and the gallium fraction correspondingly increases. In the region proximate to the diamond bonding interface 108, the composition is tuned to achieve a bandgap that closely matches the approximately 5.5 eV bandgap of diamond, thereby minimizing barriers to current flow across the heterogeneous p-n junction 106.

The grading transitions from lattice-constant matching near the growth substrate 160 to bandgap matching near the diamond interface reduces lattice mismatch strain while enabling efficient carrier transport across the junction 106. It should be understood that the specific grading profile shown is illustrative; various embodiments may employ different grading curves (e.g., linear, stepwise, or other non-linear profiles) depending on the particular growth substrate 160 and target bandgap. Additionally, in some embodiments, indium may be incorporated into the graded layer (i.e., In(x)Al(y)Ga(1-x-y)N) to achieve deeper bandgap matching with diamond.

The compositional grading profile shown in FIG. 17 is illustrative and not to scale. The specific shape of the grading curve, the starting and ending composition fractions, and the relative widths of the lattice-matching and bandgap-matching regions are exemplary and may vary depending on the growth substrate 160, the target bandgap, and the specific In(x)Al(y)Ga(1-x-y)N composition employed. Various embodiments may use linear, stepwise, or other non-linear grading profiles not depicted here.

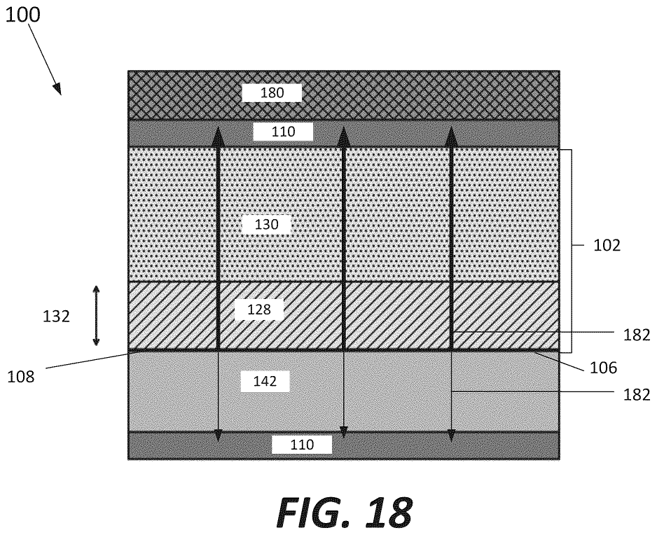

FIG. 18 schematically shows a cross-section of the semiconductor device 100 having isotopically enriched diamond substrate 102 in accordance with illustrative embodiments. As shown from bottom to top, the device 100 includes a metal contact 110 on the n-side, an n-AlGaN 142 (III-N) layer 142, a direct bond 108 interface, an isotopically enriched Carbon-12 diamond region 128, a mixed-isotope diamond region 130, a metal contact 110 or thermal interface on the p-side, and a heat sink or cooling system 180. The direct bond 108 interface is shown representatively as a thin line in FIG. 18 for clarity; it does not constitute a separate physical layer but rather represents the boundary at which the n-AlGaN 142 and the isotopically enriched Carbon-12 diamond 128 are directly bonded through covalent bonds formed between dangling bonds at each surface, as described with reference to FIG. 19.

The carbon-12 enriched region 128 may have a thickness 132 extending from the bonded interface 108 of at least about 5 microns. Below approximately 5 microns, phonon scattering effects (e.g., phonon bunching) may impair thermal transport in the diamond, reducing the thermal management benefit at the junction. The isotopically enriched Carbon-12 diamond provides enhanced thermal conductivity compared to mixed-isotope diamond (which includes both C-12 and C-13 isotopes in their naturally occurring ratio), because isotopic purity reduces phonon scattering from mass-disorder effects. In some embodiments, the diamond 102 beyond the carbon-12 enriched region 128 (e.g., mixed-isotope diamond region 130) may have a different isotopic composition, including a naturally occurring or mixed-isotope carbon composition. The mixed-isotope diamond region 130, distal from the bonding interface 108, provides the bulk mechanical support and still offers high thermal conductivity (e.g., approximately 2,000 to 2,500 W/m·K), which is sufficient for transporting heat from the C-12 enriched region to the cooling system 180 on the backside.

In various embodiments, the cooling system 180 may be air-cooled, liquid-cooled, or may include thermal fins or other heat extraction structures, depending on the deployment environment (e.g., a drone, a cell tower, a substation, or other platform). Heat generated at the p-n junction 106 flows through the isotopically enriched C-12 region 128 and the mixed-isotope diamond 130 to the cooling system 180, as indicated by the heat flow 182 direction arrows. The thick arrows extending from the junction 106 through the diamond substrate 102 toward the cooling system 180 represent the primary thermal path. This path carries the majority of the generated heat due to diamond's high thermal conductivity (e.g., approximately 2,000 to 2,500 W/m·K). The thinner arrows extending from the junction 106 in the opposite direction through the n-AlGaN 142 layer and toward the n-side metal contact 110 represent a secondary thermal path, which carries a lesser portion of the generated heat. The relative thickness of the arrows is illustrative of the relative magnitude of heat flow 182 along each path and is not drawn to scale. The double-headed arrow on the left side of the figure indicates the thickness of the isotopically enriched Carbon-12 diamond region adjacent to the bonding interface 108 (e.g., at least about 5 microns)

In various embodiments, the diamond layer 102 or diamond substrate 102 has a thickness selected to provide effective thermal transport away from the active junction region. Because heat is generated at or near the active switching junction, the diamond provides a continuous thermally conductive path from the junction region toward a backside thermal extraction structure, such as a heat sink, cooling plate, finned structure, thermally conductive mount, liquid-cooled manifold, or other thermal management system. In some embodiments, the diamond has a thickness of at least about 5 microns. A diamond layer 102 thinner than this may, in some implementations, provide reduced heat spreading or reduced thermal transport efficiency relative to a thicker diamond layer 102. Accordingly, in various embodiments, the diamond layer 102 has a thickness of at least about 5 microns, at least about 10 microns, at least about 25 microns, or more. In some embodiments, the diamond layer 102 may have a thickness between about 5 microns and about 650 microns. In other embodiments, the diamond may be thicker or thinner, depending upon device geometry, power density, cooling configuration, and fabrication constraints.

In some embodiments, the diamond 102 thickness is selected in view of both device 100 operation and manufacturability. For example, prior to bonding, one or both wafers may be kept at a greater thickness to facilitate handling and reduce fracture risk. After bonding, one or more layers may be thinned from the backside because the bonded structure provides mechanical support. Accordingly, some embodiments initially provide a thicker diamond body, and may thin the bonded structure after formation of the bonded interface.

FIG. 19 schematically shows a direct bonding process for heterogeneous integration of diamond and III-N materials in accordance with illustrative embodiments. In various embodiments, the diamond 102 and the III-nitride body 142 are directly bonded without an intervening adhesive layer, solder layer, filler layer, or polymeric bonding layer. The process is shown in four stages.

In stage (A), both the p-type diamond 102 surface and the n-type AlGaN 142 surface are exposed to ambient conditions and have surface termination layers. These termination layers may comprise oxygen-containing species, hydroxyl groups (OH), hydrogen termination, native oxide, adsorbed contaminants, or combinations thereof. Such termination layers are naturally present on any crystalline surface exposed to air and would inhibit atomic-level bonding between the two materials if not reduced or removed.

In stage (B), one or both surfaces are prepared to remove surface contamination and surface termination species. Surface preparation may include one or more of polishing, cleaning, plasma treatment, ion bombardment (e.g., using an ion beam or plasma system), etching, annealing, ultraviolet/ozone treatment, or other activation techniques. In some embodiments, the surface preparation is performed under reduced pressure or vacuum to reduce contamination and facilitate high-quality interfacial contact. The ion cleaning process strips away the oxide, hydroxyl, and other adsorbed species from both surfaces, as indicated by the scattered particle markers.

In stage (C), following surface preparation, the exposed surfaces of both the p-type diamond 102 and the n-type AlGaN 142 have chemically reactive surface bonds, commonly referred to as dangling bonds. These dangling bonds have unfilled electron orbitals and are in a metastable state, meaning they are energetically inclined to form bonds with available neighboring atoms. The open circles at the surface of each material represent these unsatisfied bonds.

In stage (D), the two prepared surfaces are brought into contact, and the reactive surface bonds from each material satisfy one another by forming direct interfacial bonds across the diamond/III-nitride interface. This creates a direct bond 108 between the p-type diamond 102 and the n-type AlGaN without the need for any intermediate adhesive, filler material, or bonding layer. In some embodiments, the direct bond 108 is formed by placing the activated surfaces into contact and optionally applying pressure and/or elevated temperature to further strengthen the bonded interface, as described elsewhere herein. Because the direct bond 108 is formed without an intervening adhesive or filler layer, the resulting bonded interface may provide improved electrical coupling, reduced thermal resistance, or both, relative to structures having an intervening material between the diamond and the III-nitride body. The bonded interface supports the formation of a high-quality p-n junction 106 with minimal interface resistance, which is advantageous for efficient device operation.

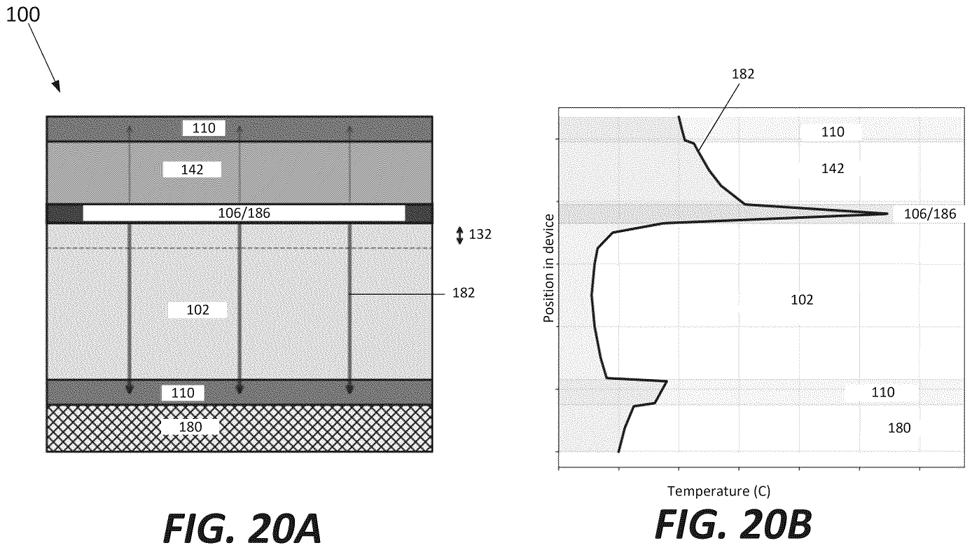

FIGS. 20A-20B schematically shows thermal management in a diamond/III-N semiconductor device 100 in accordance with illustrative embodiments. FIG. 20A shows a cross-section of the device 100 stack, including, from top to bottom: an n-side metal contact 110, an n-AlGaN 142 layer, the p-n junction 106 (identified as the heat generation zone 186), the p-type diamond 102 diamond substrate 102, a p-side metal contact 110, and a cooling system 180 (e.g., air-cooled or liquid-cooled). Arrows within the diamond substrate 102 indicate the direction of heat flow 182 from the p-n junction 106, where heat is generated during device 100 operation, through the diamond substrate 102 to the cooling system 180 on the backside. The diamond substrate 102 has a thermal conductivity (κ) of approximately 2,000 to 2,500 W/m·K, which is the highest of any known material and enables rapid dissipation of heat away from the junction. A dashed line within the diamond substrate 102 indicates the boundary of an optional isotopically enriched Carbon-12 region (at least about 5 microns thick 132) proximate to the junction 106, as described with reference to FIG. 18.

FIG. 20B shows a qualitative temperature profile along the device stack. The horizontal axis represents temperature and the vertical axis represents position within the device. As shown, the temperature peaks at the p-n junction 106, where resistive and switching losses generate heat. The temperature drops sharply through the diamond substrate 102 due to diamond's high thermal conductivity, and continues to decrease through the metal contact 110 to the cooling system 180. This temperature profile illustrates the advantage of having diamond directly at the p-n junction 106: the high thermal conductivity of diamond rapidly conducts heat away from the hottest region of the device, keeping the junction operating temperature lower than would be achievable with other substrate materials. This thermal management benefit enables higher power operation, improved switching efficiency, and greater device reliability.

Because heat generation in a semiconductor switch 100 or diode tends to occur at or near the active current-blocking and current-conducting junction region, placing highly thermally conductive diamond at or near that region can improve thermal extraction, stabilize operation, reduce temperature rise, improve reliability, and support higher power or higher frequency operation. Thus, in various embodiments, the diamond is directly bonded to a III-nitride region participating in the active junction or positioned sufficiently near the active junction that the diamond efficiently removes heat from that region. The steep temperature drop through the diamond substrate 102 reflects diamond's high thermal conductivity, which enables heat to be transported rapidly away from the junction rather than accumulating within the material. A material with lower thermal conductivity would exhibit a more gradual temperature decline, resulting in higher sustained temperatures near the junction and reduced device performance.

This arrangement differs from structures in which diamond is merely remote from the active junction or separated from the active region by one or more thermally resistive intervening layers. In some embodiments, the direct bond 108 between the diamond and the III-nitride body 142 places the diamond in immediate thermal communication with the active region.

The temperature profile shown in FIG. 20B is qualitative and illustrative of general thermal behavior; actual temperatures will depend on operating conditions, device geometry, power dissipation, diamond thickness, isotopic composition, and the specific cooling system 180 employed. In practice, thermal resistance at material interfaces, such as between the diamond substrate 102 and the metal contact 110, or between the metal contact 110 and the cooling system 180, may produce localized temperature discontinuities or variations that differ from the idealized curve shown. The profile illustrates that the diamond substrate 102 exhibits the lowest temperatures in the device stack due to its high thermal conductivity, which enables heat to be transported rapidly away from the junction rather than accumulating within the material.

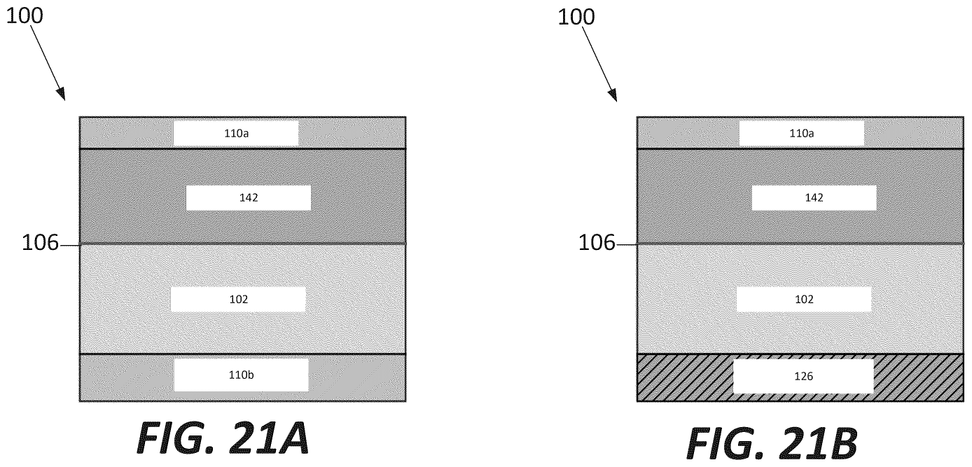

FIGS. 21A-21B schematically shows alternative backside contact configurations for the p-type diamond 102 in accordance with illustrative embodiments. FIG. 21A shows a standard configuration, corresponding generally to the structure of FIG. 7, in which a metal contact 110 (e.g., platinum or gold) is deposited on the backside of the p-type diamond 102 diamond substrate 102 to provide electrical contact to the p-side of the device 100. FIG. 21B shows an alternative configuration in which the metal contact 110 on the p-side is replaced by a heavily boron-doped diamond layer 126 having metal-like electrical conductivity. In this alternative embodiment, the boron doping concentration is sufficiently high that the diamond layer 102 exhibits electrical behavior approaching that of a metallic conductor, thereby serving as an ohmic contact to the p-type diamond 102 diamond substrate 102 without requiring a separate deposited metal layer. This configuration may provide advantages in terms of thermal expansion matching with the diamond substrate 102 and structural robustness under high-temperature, high-power operation. In both panels, the n-side metal contact 110 (e.g., aluminum or titanium), the n-AlGaN 142 layer, the p-n junction 106, and the p-type diamond 102 substrate are shown for reference. It should be understood that various embodiments may use either configuration, and that the choice between a deposited metal contact 110 and a heavily doped diamond contact 126 may depend on the specific requirements of the application, including thermal, electrical, and mechanical considerations.

In various embodiments, electrical contact to the diamond body may be provided at least in part by a highly doped diamond contact region. For example, a backside region of the p-type diamond 102 may be doped to a concentration sufficient to provide low-resistance, metal-like conduction. The highly doped diamond contact region may be used instead of, or in combination with, a metal contact 110 disposed on the diamond. In some embodiments, a metal layer is formed on the highly doped diamond contact region to provide an external terminal of the device.

FIGS. 22A and 22B schematically show the operation of the semiconductor device 100 as a switch in accordance with illustrative embodiments. The semiconductor switch 100 includes a semiconductor device 100 configured to selectively permit and/or block current flow in response to an applied electrical condition. Thus, the term includes, among other things, rectifying diodes, p-n junction 106 devices, p-i-n devices, and other semiconductor junction devices that transition between more conductive and less conductive operating states. In various embodiments, the device operates as a vertical semiconductor switch 100 in which current flows in a direction generally perpendicular to a major surface of the diamond substrate 102.

FIG. 22A shows the device in a forward bias condition, corresponding to the switch “on” state. A positive voltage (V>0) is applied to the p-type layer 102 relative to the n-type AlGaN layer 142, which overcomes the built-in electric field at the p-n junction 106. The depletion region 192 at the junction narrows, creating a conductive path and allowing current to flow vertically through the device, that is, along a direction perpendicular to the surface of the diamond substrate 102, and through an external load 190.

FIG. 22B shows the device in a reverse bias condition, corresponding to the switch “off” state. The polarity of the applied voltage is reversed (V<0), causing the depletion region 192 at the p-n junction 106 to widen significantly. The widened depletion region 192 blocks current flow through the device 100, effectively placing the switch 100 in a non-conducting state. The ultra-wide bandgap properties of both the p-type diamond 102 and the n-type AlGaN enable the device to withstand high reverse voltages (e.g., greater than 5 kV) without breakdown. The diagonal line across the load 190 indicates that no current is flowing through the load 190 in the reverse bias condition; the load 190 itself remains present in the circuit but is in a non-conducting state due to the blocked current path through the device.

The cross-sections shown in FIG. 22A-B are schematic and not to scale. The relative thicknesses of the depletion are exaggerated for clarity and are illustrative of the general operating principle rather than actual dimensions.

It should be understood that the depletion region 192 is not a separate physical layer of the device, but rather a zone within the existing p-type and n-type semiconductor materials in which mobile charge carriers have been swept away by the electric field at the junction. The widening and narrowing of the depletion region 192 under different bias conditions, as shown in FIGS. 22A and 22B, represents the redistribution of mobile charge carriers within the semiconductor layers and does not reflect a change in the physical structure, dimensions, or material properties of the device.

FIG. 23 shows a ternary bandgap diagram for the In(x)Al(y)Ga(1-x-y)N material system in accordance with illustrative embodiments. The three vertices of the triangle represent the three binary III-Nitride endpoints: aluminum nitride (AlN) at the top, having a bandgap of approximately 6.20 eV; gallium nitride (GaN) at the bottom left, having a bandgap of approximately 3.42 eV; and indium nitride (InN) at the bottom right, having a bandgap of approximately 0.69 eV. Each point within the triangle corresponds to a specific ternary or quaternary alloy composition of In(x)Al(y)Ga(1-x-y)N, and the contour lines indicate compositions sharing the same bandgap energy.

As shown, the bandgap of the III-N alloy is continuously tunable across a wide range by adjusting the relative proportions of indium, aluminum, and gallium. The aluminum fraction has the strongest influence on increasing the bandgap toward the ultra-wide bandgap regime, while increasing indium content reduces the bandgap. To achieve a bandgap approximately matching that of diamond (approximately 5.5 eV), the aluminum fraction may be greater than about 0.85, with correspondingly low gallium and indium fractions. The 5.5 eV contour line, visible near the apex of the triangle, identifies the compositional window suitable for bandgap matching with diamond.

In various embodiments, the composition of the In(x)Al(y)Ga(1-x-y)N layer 142 at or near the diamond bonding interface 108 may be selected from this high-aluminum region to minimize bandgap discontinuity at the p-n junction 106, thereby reducing barriers to current flow and enabling superior diode characteristics. Compositions further from the bonding interface 108 may have lower aluminum fractions to accommodate lattice matching with the growth substrate 160 (e.g., SiC, sapphire, AlN, or GaN), as described with reference to the compositional grading profile of FIG. 17. Thus, FIG. 23 may be read in conjunction with FIG. 17 to understand how the composition transitions from a lattice-matching region 212 near the growth substrate 160 to a bandgap-matching region 214 near the diamond interface.

It should be noted that the bandgap values shown in FIG. 23 are approximate and represent room-temperature values for unstrained alloys. Actual bandgap values in a fabricated device may vary due to strain, doping, temperature, and other factors. The figure is provided to illustrate the general relationship between composition and bandgap across the full In(x)Al(y)Ga(1-x-y)N material system and to identify the compositional region relevant to bandgap matching with diamond.

Additionally, while FIG. 23 shows that increasing indium content generally reduces the bandgap of the III-N alloy, indium may nevertheless be incorporated in some embodiments for purposes other than bandgap matching, such as strain management, lattice engineering, or modification of polarization properties within the graded heterostructure.

In various embodiments, the composition of the In(x)Al(y)Ga(1-x-y)N layer 142 may be selected to achieve a bandgap suitable for integration with the diamond substrate 102. As used herein, the composition fractions x, y, and (1-x-y) in the expression In(x)Al(y)Ga(1-x-y)N refer to the relative atomic fractions of the Group III elements (indium, aluminum, and gallium, respectively) and do not include nitrogen, which is present in a stoichiometric ratio as the Group V element. As shown in FIG. 23, the bandgap of the III-N alloy is continuously tunable by adjusting the relative proportions of aluminum, gallium, and indium. Aluminum is essential for achieving bandgaps in the ultra-wide bandgap regime; without aluminum (i.e., using only gallium and indium), the maximum achievable bandgap is approximately 3.42 eV (pure GaN), which is insufficient for bandgap matching with diamond. However, the aluminum fraction is maintained below approximately 0.98 because pure or near-pure AlN has a bandgap of approximately 6.20 eV, which exceeds the approximately 5.5 eV bandgap of diamond; accordingly, some dilution of aluminum with gallium and/or indium is used to reduce the bandgap of the III-N alloy to a value suitable for bandgap matching with diamond. Broadly, compositions useful in the heterostructure of various embodiments may include an aluminum fraction in the range of approximately 0.60 to less than approximately 0.98, a gallium fraction in the range of approximately 0.02 to approximately 0.35, and an indium fraction in the range of approximately 0.00 to approximately 0.25, where the sum of the aluminum, gallium, and indium fractions equals approximately 1.00. It should be understood that not all combinations within these individual ranges are simultaneously achievable, as the fractions are interdependent; for example, a composition having an indium fraction of 0.25 would require a correspondingly reduced combined aluminum and gallium fraction. Within this compositional space, as shown in FIG. 23, bandgaps ranging from approximately 4.0 eV to approximately 6.2 eV are achievable, encompassing compositions suitable for graded transition regions, intermediate buffer layers, and regions proximate to the diamond bonding interface 108. As demonstrated by the inventors, high-quality pseudomorphic Al0.74Ga0.26N films exceeding 1 μm in thickness have been epitaxially grown on bulk AlN substrates (see FIG. 1C), confirming the ability to produce device-quality material at aluminum fractions well within this range.

For embodiments in which close bandgap matching with diamond is desired—for example, to minimize bandgap discontinuity at the p-n junction 106, reduce barriers to current flow, or optimize diode ideality factor, the aluminum fraction at or near the diamond bonding interface 108 may be in the narrower range of approximately 0.80 to less than approximately 0.98, with a corresponding gallium fraction of approximately 0.02 to approximately 0.20 and an indium fraction of approximately zero. This narrower compositional window corresponds to bandgaps in the range of approximately 5.0 eV to approximately 5.8 eV, which most closely approaches the approximately 5.5 eV bandgap of diamond. It should be understood that an exact bandgap match is not required in all embodiments; compositions providing a close but not exact match may offer other advantages, such as reduced strain, improved crystalline quality, or compatibility with demonstrated growth processes. Additionally, while indium generally reduces the bandgap of the III-N alloy as shown in FIG. 23, indium may nevertheless be incorporated in some embodiments within the broader compositional range described above for purposes such as strain management, lattice engineering, or modification of polarization properties within the graded heterostructure. The specific composition at any point in the heterostructure may be selected based on the combined requirements of bandgap, lattice constant, strain, polarization, and other material properties relevant to the particular device design, and these ranges are approximate and illustrative rather than limiting

Within this compositional space, as shown in FIG. 23, bandgaps ranging from approximately 4.0 eV to approximately 6.2 eV are achievable, encompassing compositions suitable for graded transition regions, intermediate buffer layers, and regions proximate to the diamond bonding interface 108. As demonstrated by the inventors, high-quality pseudomorphic Al0.74Ga0.26N films exceeding 1 μm in thickness have been epitaxially grown on bulk AlN substrates (see FIG. 1C), confirming the ability to produce device-quality material at aluminum fractions well within this range.

For various embodiments in which close bandgap matching with diamond is desired—for example, to minimize bandgap discontinuity at the p-n junction 106, reduce barriers to current flow, or optimize diode ideality factor—the aluminum fraction at or near the diamond bonding interface 108 may be in the narrower range of approximately 0.80 to approximately 0.98, with a corresponding gallium fraction of approximately 0.02 to approximately 0.20 and an indium fraction of approximately zero. This narrower compositional window corresponds to bandgaps in the range of approximately 5.0 eV to approximately 6.2 eV, which most closely approaches the approximately 5.5 eV bandgap of diamond. It should be understood that an exact bandgap match is not required in all embodiments; compositions providing a close but not exact match may offer other advantages, such as reduced strain, improved crystalline quality, or compatibility with demonstrated growth processes.

In some embodiments, one or more layers of the In(x)Al(y)Ga(1-x-y)N heterostructure may be doped using polarization-induced doping techniques, in which compositional grading or short-period superlattice structures within the III-N material generate bound polarization charges that induce free carriers without requiring conventional impurity dopants. For example, alternating layers of differing AlGaN compositions within a short-period superlattice region may cause modulation of the valence band or conduction band potential, thereby inducing p-type or n-type conductivity, respectively. Such polarization-engineered layers may be incorporated into the III-N body that is subsequently directly bonded to the diamond substrate 102, enabling tailored electrical properties within the vertical device architecture described herein

Additionally, while indium generally reduces the bandgap of the III-N alloy as shown in FIG. 23, indium may nevertheless be incorporated in some embodiments within the broader compositional range described above for purposes such as strain management, lattice engineering, or modification of polarization properties within the graded heterostructure. The specific composition at any point in the heterostructure may be selected based on the combined requirements of bandgap, lattice constant, strain, polarization, and other material properties relevant to the particular device design, and these ranges are approximate and illustrative rather than limiting.

Throughout this description, the semiconductor device 100 is frequently referred to as a switch or semiconductor switch for purposes of illustration, as switching is a principal intended application of the device. It should be understood that the semiconductor device 100 is not limited to use as a switch. The same device structure—comprising a diamond body directly bonded to an In(x)Al(y)Ga(1-x-y)N layer forming a p-n junction with current flow perpendicular to the bonding interface—may also function as, or be incorporated into, a diode, a rectifier, a power converter, a voltage regulator, an RF device, a high-frequency amplifier, a sensor, or other electronic component, depending on the operating conditions, circuit configuration, and application requirements. Accordingly, references to the device as a ‘switch’ should be understood as illustrative and not limiting of the scope of the invention.

As used in this specification and the claims, the singular forms “a,” “an,” and “the” refer to plural referents unless the context clearly dictates otherwise. For example, reference to “the layer” in the singular includes a plurality of layers, and reference to “the dopant” in the singular includes one or more dopants and equivalents known to those skilled in the art. Thus, in various embodiments, any reference to the singular includes a plurality, and any reference to more than one component can include the singular.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein.

It is, therefore, to be understood that the foregoing embodiments are presented by way of example only and that, within the scope of the appended claims and equivalents thereto, inventive embodiments may be practiced otherwise than as specifically described and claimed. Illustrative embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure. Disclosed embodiments, or portions thereof, may be combined in ways not listed above and/or not explicitly claimed. Thus, one or more features from variously disclosed examples and embodiments may be combined in various ways. For example, it is to be understood that the present disclosure contemplates that, to the extent possible, one or more features of any embodiment can be combined with one or more features of any other embodiment.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

1. A semiconductor switch, comprising:
a synthetic diamond substrate;
an In₍ₓ₎Al_{(y)}Ga_{(1-x-y)}N layer disposed on a surface of said diamond substrate;
a p-n junction configured so that current flows along a direction perpendicular to the surface of said diamond substrate;
whereby, said diamond, In₍ₓ₎Al_{(y)}Ga_{(1-x-y)}N layer, and p-n junction together form a switch,
metal contacts in electrical contact with the diamond substrate and with the In₍ₓ₎Al_{(y)}Ga_{(1-x-y)}N layer, wherein the switch is configured to turn on when a voltage bias is applied across said p-n junction.

2. The semiconductor switch of claim 1, wherein said p-n junction is at the diamond-InAlGaN interface.

3. The semiconductor switch of claim 2, wherein the diamond is p-type doped and the InAlGaN is n-type doped.

4. The semiconductor switch of claim 3, wherein the p-doping element is Boron and the n-doping element is one of Silicon, Germanium, or Oxygen.

5. The semiconductor switch of claim 3, wherein the p-doping element is Boron and the n-doping is realized by grading the Al-composition from low-to-high in the growth direction of an Al- or Ga-polar substrate or template.

6. The semiconductor switch of claim 2, wherein the diamond is n-type doped and the InAlGaN is p-type doped.

7. The semiconductor switch of claim 5, wherein the n-doping is one of Phosphorous or Nitrogen and the p-doping element is one of Magnesium, Zinc, or Beryllium.

8. The semiconductor switch of claim 1, wherein the InAlGaN is a heterostructure comprising various alloy compositions of In, Al, Ga, and N.

9. The semiconductor switch of claim 1, wherein the epitaxial InAlGaN is a heterostructure comprising gradually changing alloy compositions to induce n- or p-type conductivity via polarization doping.

10. The semiconductor switch of claim 7, wherein said p-n junction is formed within the heterostructure layer.

11. The semiconductor switch of claim 7, wherein the heterostructure comprises epitaxial layers with bandgaps in the range between 4 eV and 6.2 eV.

12. The semiconductor switch of claim 7, wherein the heterostructure comprises superlattices, short period superlattices, or graded alloy compositions.

13. The semiconductor switch of claim 10, wherein the heterostructure further includes polarization-doping structures that induce enhanced free carrier generation.

14-17. (canceled)

18. A hybrid semiconductor switch, comprising:
a synthetic diamond substrate;
an epitaxial InAlGaN thin film disposed on said diamond substrate;
a p-n junction configured so that current flows along a direction perpendicular to said diamond substrate;
and an intrinsic, un-doped film between the p-n junction;
whereby, said diamond, InAlGaN, and p-i-n junction together form a switch metal contacts in electrical contact with the diamond substrate and with the InAlGaN thin film, wherein applying a voltage bias across said p-n junction turns the switch on or off.

19. The semiconductor switch of claim 18, wherein the intrinsic material is one of SiO2, Al2O3, AlN, AlGaN, SiN, HfO2, etc.

20. A method for forming a hybrid semiconductor switch, comprising:
polishing the surface of a synthetic diamond substrate;
wafer bonding an InAlGaN heterostructure on said diamond substrate by disposing a surface of the heterostructure against the polished surface of the diamond substrate, applying pressure to enhance contact between the surfaces, and applying temperature to induce interaction of surface atoms;
wherein the bonded structure comprises a p-n or p-i-n junction along a direction perpendicular to said diamond substrate; the p-n or p-i-n junction allowing electrical current flow if forward biased and blocking electrical current flow if reverse biased.

21. The method of claim 20, further comprising additional thermal anneals to induce interface atom diffusion after wafer bonding.

22. The method of claim 20, wherein one or both surfaces are activated with plasma treatment.

23. The method of claim 20, wherein one or both substrates are further thinned using mechanical polishing, wet chemical etching, or a combination of both processes.

24. The method of claim 23, wherein the one or both substrates are thinned down to between about 50 um and about 1 mm thick.

25-65. (canceled)
